(19) United States
(12) Patent Application Publication
(10) Pub. No.: US 2012/0327967 A1
(43) Pub. Date: Dec. 27, 2012

(54) GROUP III NITRIDE SEMICONDUCTOR LASER DEVICE, EPITAXIAL SUBSTRATE, METHOD OF FABRICATING GROUP III NITRIDE SEMICONDUCTOR LASER DEVICE

(75) Inventors: Yohei ENYA, Itami-shi (JP); Yusuke YOSHIZUMI, Itami-shi (JP); Takashi KYONO, Itami-shi (JP); Takamichi SUMITOMO, Itami-shi (JP); Masaki UENO, Itami-shi (JP); Katsunori YANASHIMA, Kanagawa (JP); Kunihiko TASAI, Tokyo (JP); Hiroshi NAKAJIMA, Kanagawa (JP)

(73) Assignees: SONY CORPORATION, TOKYO (JP); SUMITOMO ELECTRIC INDUSTRIES, LTD., Osaka-shi (JP)

(21) Appl. No.: 13/480,178

(22) Filed: May 24, 2012

(30) Foreign Application Priority Data
May 25, 2011 (JP) 2011-117164

(51) Int. Cl. H01S 5/323; H01L 33/32

(52) U.S. Cl. 372/45.011; 438/47; 257/E33.025

(57) ABSTRACT

A nitride semiconductor laser device includes a p-type cladding layer, an active layer and an n-type cladding layer. The p-type cladding layer and the n-type cladding layer comprise indium and aluminum as group-III constituent. The n-type cladding layer, active layer and p-type cladding layer are arranged along the normal of a semi-polar semiconductor surface of a substrate. This surface tilts toward the m-axis of the hexagonal nitride by an angle of 63 degrees or more and smaller than 80 degrees from a plane orthogonal to a reference axis extending along the c-axis thereof. The active layer generates light having a peak wavelength in the range of 480 to 600 nm. The refractive indices of the n-type cladding layer and p-type cladding layer are smaller than that of GaN. The n-type cladding layer has a thickness of 2 μm or more while the p-type cladding layer has a thickness of 500 nm or more.

### BACKGROUND OF THE INVENTION

1. Field of the Invention

The present invention relates to a nitride semiconductor laser device, an epitaxial substrate, and a method of fabricating a nitride semiconductor laser device.

2. Related Background Art

Patent Literature 1 discloses a nitride semiconductor light-emitting device formed on a c-plane. The nitride semiconductor light-emitting device includes two ternary AlGaN cladding layers. The light emitted from the nitride semiconductor light-emitting device has a wavelength between approximately 410 and 455 nm, which is a wavelength equal to or shorter than that of blue light.
Patent Literature 1: Japanese Patent No. 3538275

### SUMMARY OF THE INVENTION

As mentioned in Patent Literature 1, a thick AlGaN cladding layer cracks. The thickness of such an AlGaN cladding layer is also limited by the critical thickness.

The light emitting device disclosed in Patent Literature 1 emits light having a wavelength in the range of 410 and 455 nm. At a wavelength region longer than that of light emitted from the light emitting device in Patent Literature 1, a difference in the refractive index between an active layer and a cladding layer is smaller than that in the above wavelength region due to wavelength dispersion in the nitride material. This is because the difference in the refractive index between GaN and AlGaN decreases within that wavelength region. To compensate for such a decrease in refractive index difference, the AlGaN layer must have a large aluminum content and/or a large thickness. But, the thickness of an AlGaN cladding layer is limited by the critical thickness whereas an increase in the aluminum content in the AlGaN reduces the critical thickness.

Changing the thickness of the cladding layer is not enough for a light emitting device on the c-plane to generate light having, for example, a wavelength longer than that of blue light. The use of the c-plane in the production of a light emitting device capable of emitting long-wavelength light results in the generation of a large piezoelectric field and a inhomogeneous indium distribution in the InGaN light emitting layer.

During growth of a quaternary InAlGaN mixed crystal in the c-plane, the growth temperature of the AlN associated with aluminum of a group-III element is quite different from the growth temperature of InN associated with indium of a group-III element. Since indium is a constituent of this mixed crystal, the relevant nitride semiconductor is grown at, for example, a temperature lower than the growth temperature of GaN. The nitride semiconductor grown over the c-plane does not have a desired surface morphology due to an increase in thickness. This does not provide satisfactory light-emitting characteristics. The present inventors presume that a thick quaternary InAlGaN mixed crystal having sufficient surface morphology cannot be grown due to reasons associated with the above growth mechanism.

Group-III nitride semiconductor light-emitting devices are about to be achieved which emits light having a wavelength longer than that of blue light, in other words, green lasing. A requirement for the generation of such a semiconductor laser beam having a long wavelength is a decrease in lasing threshold current. To achieve such a decrease, a cladding structure that compensates for the decrease in the difference between the refractive indices due to wavelength dispersion in the nitride semiconductor material should be provided.

It is an object of one aspect of the present invention to provide a nitride semiconductor laser device having a cladding structure suitable for long-wavelength lasing. It is an object of another aspect of the present invention to provide an epitaxial substrate of a nitride semiconductor laser device. It is an object of still another aspect of the present invention to provide a method of fabricating a nitride semiconductor laser device.

A nitride semiconductor laser device according to one aspect of the present invention comprises: (a) an n-type cladding layer comprising a first nitride semiconductor which comprises indium and aluminum as group-III constituents; (b) an active layer having an epitaxial layer which comprises a nitride semiconductor, the nitride semiconductor comprising indium as a group-III constituent; and (c) a p-type cladding layer comprising a second nitride semiconductor which comprises indium and aluminum as group-III constituents. The n-type cladding layer, the active layer, and the p-type cladding layer are provided over a semi-polar semiconductor surface comprising a hexagonal nitride semiconductor; the n-type cladding layer, the active layer, and the p-type cladding layer are arrayed along a axis normal to the semi-polar semiconductor surface; the semi-polar semiconductor surface tilts toward an m-axis of the hexagonal nitride semiconductor by an angle of larger than or equal to 63 degrees and smaller than 80 degrees from a reference plane orthogonal to a reference axis which extends along the c-axis of the hexagonal nitride semiconductor; the active layer is provided between the n-type cladding layer and the p-type cladding layer; the active layer emits light having a peak wavelength within a range of 480 to 600 nm; the refractive index of the n-type cladding layer and the refractive index of the p-type cladding layer are smaller than the refractive index of GaN; and the n-type cladding layer has a thickness of 2 μm or more while the p-type cladding layer has thickness of 500 nm or more.

In the group-III nitride semiconductor laser device, the n-type cladding layer is composed of a nitride semiconductor containing indium and aluminum as group-III constituents, while the p-type cladding layer is composed of a nitride semiconductor containing indium and aluminum as group-III constituents. In the nitride semiconductor, the growth temperature of AlN associated with aluminum, which is a group-III constituent element, is quite different from the growth temperature of InN associated with indium, which is also a group-III constituent element. Thus, the nitride semiconductor is grown at, for example, a temperature lower than the growth temperature of GaN. The nitride semiconductor grown over the c-plane does not have sufficient surface morphology due to an increase in thickness. Thick n-type and p-type cladding layers cannot be readily grown due to a difference in the growth temperature between MN and InN. Thus, satisfactory surface morphology is not obtained.

A semi-polar semiconductor surface tilts by the angle in the range mentioned above. Step-flow growth of the nitride semiconductor occurs over the semi-polar surface, which tilts by an angle in the range mentioned above, at the low temperature mentioned above. Thus, a cladding layer can be composed of a thick nitride semiconductor. The cladding layer, which is composed of such a nitride semiconductor, has excellent surface morphology. A core semiconductor region including the active layer can be provided over the semi-polar surface with such excellent surface morphology. Consequently, the active layer has excellent crystal quality. The surface of a core semiconductor region is semi-polar within the angle range mentioned above; hence, similar to the cladding layer described above, the cladding layer provided over the active layer can be composed of a thick nitride semiconductor. Thus, the n-type cladding layer is composed of a thick first nitride semiconductor while the p-type cladding layer is composed of a thick second nitride semiconductor.

The difference in the refractive index between the cladding and the core is small for light emitted from the active layer having a peak wavelength within the range of 480 to 600 nm, due to wavelength dispersion in the nitride semiconductor. The refractive index difference in this wavelength the range is smaller than, for example, that in the wavelength range of blue light. In other words, the change of nitride semiconductor materials to improve the refractive index difference cannot be used to obtain the enhancement of optical confinement.

A semi-polar surface tilting within the above-mentioned range can provide the growth of an n-type cladding layer having a thickness of 2 μm or more and a p-type cladding layer having a thickness of 500 nm or more. Accordingly, the thick nitride semiconductors having a refractive index smaller than that of GaN can compensate for a refractive index difference reduction caused by wavelength dispersion.

The nitride semiconductor laser device according to one aspect of the present invention may further include a support base comprising a hexagonal group-III nitride semiconductor. The support base includes the semi-polar semiconductor surface, and the n-type cladding layer, the active layer and the p-type cladding layer are sequentially arranged on the semi-polar semiconductor surface. In the present invention, the semi-polarity of the semi-polar semiconductor surface can be defined by a support base comprising a hexagonal group-III nitride semiconductor.

Another aspect of the present invention relates to an epitaxial substrate of the nitride semiconductor laser device. The epitaxial substrate comprises: (a) an n-type cladding layer comprising a first nitride semiconductor which comprises indium and aluminum as group-III constituents; (b) an active layer having an epitaxial layer which comprises a nitride semiconductor, the nitride semiconductor comprising indium as a group-III constituent; (c) a p-type cladding layer comprising a second nitride semiconductor which comprises indium and aluminum as group-III constituents; and (d) a substrate having a semi-polar semiconductor surface composed of a nitride. The n-type cladding layer, the active layer and the p-type cladding layer are provided over a semi-polar semiconductor surface comprising a hexagonal nitride semiconductor; the n-type cladding layer, the active layer and the p-type cladding layer are arrayed along a normal axis of the semi-polar semiconductor surface; the semi-polar semiconductor surface inclined toward an m-axis of the nitride semiconductor by an angle of larger than or equal to 63 degrees and smaller than 80 degrees from a reference plane orthogonal to a reference axis extending along the c-axis of the nitride semiconductor; the active layer is provided between the n-type cladding layer and the p-type cladding layer; the active layer emits light having a peak wavelength within a range of 480 to 600 nm; the refractive index of the n-type cladding layer and the refractive index of the p-type cladding layer are smaller than the refractive index of GaN; and the n-type cladding layer has a thickness of 2 μm or more and the p-type cladding layer has thickness of 500 nm or more.

In the epitaxial substrate, the n-type cladding layer is composed of a nitride semiconductor containing indium and aluminum as group-III constituents, while the p-type cladding layer is composed of a nitride semiconductor containing indium and aluminum as group-III constituents. In the nitride semiconductor, the growth temperature of MN relating to aluminum, which is a group-III constituent element, is quite different from the growth temperature of InN relating to indium, which is also a group-III constituent element. Thus, the nitride semiconductor is grown at, for example, a temperature lower than the growth temperature of GaN. The nitride semiconductor grown over the c-plane does not have excellent surface morphology due to an increase in thickness. It is not easy to grow thick films for n-type and p-type cladding layers because of a significant difference in the growth temperature between AlN and InN, and thus their surface morphology does not have any desired quality.

A semi-polar semiconductor surface of the substrate tilts by the angle in the range mentioned above. Step-flow growth of the nitride semiconductor occurs over the semi-polar surface, which tilts by an angle within the range mentioned above, at the low temperature mentioned above. Thus, a cladding layer can be provided with a thick nitride semiconductor. The n-type cladding layer, which is composed of such a nitride semiconductor, has excellent surface morphology. A core semiconductor region including the active layer can be provided over the semi-polar surface with such excellent surface morphology. Consequently, the active layer has excellent crystal quality. The surface of a core semiconductor region is semi-polar within the angle range mentioned above; similar to the cladding layer described above, the cladding layer provided over the active layer can be composed of a thick nitride semiconductor. Thus, an n-type cladding layer composed of a thick first nitride semiconductor is provided over the substrate while a p-type cladding layer composed of a thick second nitride semiconductor is provided over the substrate. Consequently, the surface morphology is satisfactory.

When the active layer is provided over the substrate so as to emit light having a peak wavelength within the range of 480 to 600 nm, the difference in the refractive index between the cladding and the core is small due to wavelength dispersion in the nitride semiconductor. The difference of the refractive index is smaller than, for example, that in the wavelength range of blue light. In other words, the refractive index difference the between nitride semiconductor materials cannot be used to improve optical confinement.

Since the substrate has a semi-polar surface with an inclination angle in the above-mentioned range, the n-type cladding layer can be provided with a thickness of 2 μm or more and the p-type cladding layer can be provided with a thickness of 500 nm or more. Accordingly, the thick nitride semiconductors having a refractive index smaller than that of GaN can compensate for a reduction in the refractive index difference resulting from wavelength dispersion.

Still another aspect of the present invention relates to a method of fabricating a nitride semiconductor laser device. The method comprises the steps of: (a) preparing a substrate having a semi-polar semiconductor surface comprising a hexagonal nitride semiconductor; (b) growing an n-type cladding layer having a thickness of 2 μm or more over the semi-polar semiconductor surface; (c) after growing the n-type cladding layer on the semi-polar semiconductor surface, growing an active layer over the n-type cladding layer, the active layer generating light having a peak wavelength within a range of 480 to 600 nm; and (d) after growing the active layer on the semi-polar semiconductor surface, growing a p-type cladding layer having a thickness of 500 nm or more over the active layer. The n-type cladding layer comprises a first nitride semiconductor which comprises indium and aluminum as group-III constituents; the p-type cladding layer comprises a second nitride semiconductor which comprises indium and aluminum as group-III constituents; the active layer has an epitaxial layer comprising a nitride semiconductor which comprises indium as a group-III constituent; the n-type cladding layer, the active layer and the p-type cladding layer are arranged along a normal axis of the semi-polar semiconductor surface; the semi-polar semiconductor surface tilts toward an m-axis of the hexagonal nitride semiconductor by an angle of larger than or equal to 63 degrees and smaller than 80 degrees from a reference plane orthogonal to the reference axis that extends along the c-axis of the hexagonal nitride semiconductor; and the refractive index of the n-type cladding layer and the refractive index of the p-type cladding layer are smaller than the refractive index of GaN.

In this production process, the n-type cladding layer of the nitride semiconductor laser device is composed of a nitride semiconductor containing indium and aluminum as group-III constituents while the p-type cladding layer is composed of a nitride semiconductor containing indium and aluminum as group-III constituents. For the growth of the nitride semiconductor, the growth temperature of AlN containing aluminum, which is a group-III constituent, is quite different from the growth temperature of InN containing indium, which is a group-III constituent. Thus, the nitride semiconductors are grown at a temperature lower than the growth temperature of GaN, for example. The nitride semiconductor grown over the c-plane does not have excellent surface morphology due to an increase in thickness. It is not easy to grow thick films for the n-type and p-type cladding layers because of a significant difference in the growth temperature between AlN and InN, their surface morphology has a desired quality.

A semi-polar semiconductor surface tilts by the angle within the range mentioned above. Step-flow growth of the nitride semiconductor occurs over the semi-polar surface, which tilts by an angle in the range mentioned above, at the low temperature mentioned above. Thus, a cladding layer can be composed of a thick n-type nitride semiconductor. The n-type cladding layer, which is composed of such a nitride semiconductor, has excellent surface morphology. A core semiconductor region including the active layer can be provided over the semi-polar surface with such excellent surface morphology. Consequently, the active layer has excellent crystal quality. The surface of a core semiconductor region is semi-polar within the angle range mentioned above; hence, similar to the n-type thick cladding layer described above, the p-type cladding layer can be composed of a thick nitride semiconductor. Thus, the n-type cladding layer is composed of a thick first nitride semiconductor while the p-type cladding layer is composed of a thick second nitride semiconductor.

When the active layer is provided so as to emit light having a peak value in the wavelength range of 480 to 600 nm, the refractive index difference between the cladding and the core is small due to wavelength dispersion resulting from the nitride semiconductor. The refractive index difference in this wavelength range is smaller than, for example, the wavelength range of blue light. In other words, optical confinement cannot be enhanced by the difference of the refractive index between nitride semiconductor materials. A semi-polar surface tilting within the above-mentioned range technically contributes to the growth of an n-type cladding layer having a thickness of 2 μm or more and a p-type cladding layer having a thickness of 500 nm or more. Accordingly, the thick nitride semiconductors having a refractive index smaller than that of GaN can compensate for a reduction in the refractive index difference due to wavelength dispersion.

The method of fabricating a nitride semiconductor laser device according to still another aspect of the present invention, may further comprise the steps of growing a p-type contact layer over the semi-polar semiconductor surface after growing the p-type cladding layer; and forming an electrode in contact with the p-type contact layer. The epitaxial layer preferably comprises ternary InGaN having an indium content of 0.2 or more, and preferably the growth temperature of growth of the active layer to the p-type contact layer is 950 degrees Celsius or lower.

In this method, a growth temperature of 900 degrees Celsius or lower reduces thermal stress applied to the InGaN layer with a high indium content in the active layer that emits long-wavelength light.

The method of producing a nitride semiconductor laser device according to still another aspect of the present invention, may further comprise growing a nitride gallium layer over the n-type cladding layer at 1000 degrees Celsius or higher, before growing the active layer. The growth temperature of the n-type cladding layer is preferably 900 degrees Celsius or lower, and preferably the growth temperature of the active layer is 900 degrees Celsius or lower. Preferably, the semi-polar semiconductor surface is composed of GaN.

Since the growth temperature in this method is 1000 degrees Celsius or higher, GaN with excellent crystal quality can be grown before growing the active layer, which generates long-wavelength light.

In the nitride semiconductor laser device, the epitaxial substrate, and the method of fabricating the nitride semiconductor laser device and the epitaxial substrate, the epitaxial layer preferably comprises ternary InGaN having an indium content of 0.2 or more.

Since the active layer according to the above aspects of the present invention is provided over the semi-polar surface tilting at an angle that is larger than or equal to 63 degrees and smaller than 80 degrees, the step-flow growth on the semi-polar surface contributes technically to the growth of InGaN.

In the nitride semiconductor laser device, the epitaxial substrate, and the method of fabricating a nitride semiconductor laser device according to the above aspects of the present invention, the total thickness of the n-type cladding layer and the p-type cladding layer is preferably 3 μm or more. According to the present invention, the total thickness of the n-type cladding layer and the p-type cladding layer is 3 μm or more, so that satisfactory optical confinement can be obtained within the wavelength range of the light emitted from the active layer.

In the nitride semiconductor laser device, the epitaxial substrate, and the method of fabricating a nitride semiconductor laser device according to the above aspects of the present invention, the maximum refractive index of a core semiconductor region provided between the n-type cladding layer and the p-type cladding layer and including the active layer is preferably greater than or equal to the refractive index of GaN. According to the present invention, optical confinement can be achieved in the core semiconductor region having a large refractive index due to the thick n-type cladding layer and thick p-type cladding layer.

In the nitride semiconductor laser device, the epitaxial substrate, and the method of producing a nitride semiconductor laser device according to the above aspects of the present invention, the n-type cladding layer preferably has an indium content of 0.01 or more while the n-type cladding layer has an aluminum content of 0.03 or more, and the p-type cladding layer preferably has an indium content of 0.01 or more while the p-type cladding layer has an aluminum content of 0.03 or more.

According to the present invention, unlike AlGaN, the indium content of 0.01 or greater can control the lattice mismatch. Unlike InGaN layers, the aluminum content of 0.03 or higher enables increased bandgap energy and small indices of refraction.

In the nitride semiconductor laser device, the epitaxial substrate, and the method of fabricating a nitride semiconductor laser device according to the above aspects of the present invention, the first nitride semiconductor of the n-type cladding layer preferably comprises gallium as a group-III constituent, and the second nitride semiconductor of the p-type cladding layer preferably comprises gallium as a group-III constituent. According to the present invention, a material containing In, Al, and Ga as group-III constituents can be applied to the first and second nitride semiconductors.

The nitride semiconductor laser device and the epitaxial substrate according to the above aspects of the present invention may further comprise a first GaN optical guiding layer provided between the n-type cladding layer and the active layer; a first InGaN optical guiding layer provided between the first GaN layer and the active layer, a second GaN optical guiding layer provided between the p-type cladding layer and the active layer; and a second InGaN optical guiding layer provided between the second GaN optical guiding layer and the active layer. The active layers are preferably provided between the first GaN and InGaN optical guiding layers and the second GaN and InGaN optical guiding layers.

The optical guiding regions provided between the active layer and the respective cladding layers include at least two layers (InGaN layer and GaN layer) each having a refraction index different from one another, thereby reducing strain and avoid a decrease in the difference between the refractive index of the cladding and the refractive index of the core.

The nitride semiconductor laser device and the epitaxial substrate according to the above aspects of the present invention may further include an electron blocking layer provided between the p-type cladding layer and the active layer. The semi-polar semiconductor surface comprises GaN, the electron blocking layer comprises GaN, and the electron blocking layer forms junctions with two InGaN layers to be sandwiched therebetween. According to the present invention, the electron blocking layer composed of GaN can prevent the core semiconductor region, which is provided between the cladding layers, from having the reduced effective refractive index.

In the nitride semiconductor laser device, the epitaxial substrate, and the method of fabricating a nitride semiconductor laser device according to the above aspects of the present invention, the semi-polar semiconductor surface may tilt by an angle of larger than or equal to 70 degrees and smaller than 80 degrees. Such tilting preferably allows an active layer to emit long-wavelength light.

In the nitride semiconductor laser device and the epitaxial substrate according to the above aspects of the present invention, the first nitride semiconductor of the n-type cladding layer preferably has an indium content and an aluminum content such that a lattice constant of the a-axis matches a lattice constant of the a-axis of the hexagonal group-III nitride semiconductor.

In the nitride semiconductor laser device and the epitaxial substrate according to an aspect of the present invention, the second nitride semiconductor of the p-type cladding layer preferably has an indium content and an aluminum content such that a lattice constant of the a-axis matches a lattice constant of the a-axis of the hexagonal group-III nitride semiconductor.

In the nitride semiconductor laser device and the epitaxial substrate according to the above aspects of the present invention, the first nitride semiconductor of the n-type cladding layer preferably has an indium content and an aluminum content such that a lattice constant of the c-axis matches a lattice constant of the c-axis of the hexagonal group-III nitride semiconductor.

In the nitride semiconductor laser device and the epitaxial substrate according to the above aspects of the present invention, the second nitride semiconductor of the p-type cladding layer preferably has an indium content and an aluminum content such that a lattice constant of the c-axis matches a lattice constant of the c-axis of the hexagonal group-III nitride semiconductor.

In the nitride semiconductor laser device and the epitaxial substrate according to the above aspects of the present invention, the second nitride semiconductor of the p-type cladding layer preferably has an indium content and an aluminum content such that lattice constants of the c-axis and the a-axis does not match lattice constants of the c-axis and a a-axis of the hexagonal group-III nitride semiconductor, respectively, and the first nitride semiconductor of the n-type cladding layer preferably has an indium content and an aluminum content such that lattice constants of the c-axis and the a-axis does not match lattice constants of the c-axis and a a-axis of the hexagonal group-III nitride semiconductor, respectively. The first nitride semiconductor is slightly strained in the directions of the c-axis and the a-axis. The second nitride semiconductor is slightly strained in the directions of the c-axis and the a-axis.

In the nitride semiconductor laser device and the epitaxial substrate according to the above aspects of the present invention, the second nitride semiconductor of the p-type cladding layer preferably has an indium content and an aluminum content such that one of a lattice constant of the c-axis and a lattice constant of the a-axis matches the corresponding lattice constant of the c-axis and the a-axis of the hexagonal nitride semiconductor, and the first nitride semiconductor of the n-type cladding layer preferably has an indium content and an aluminum content such that the other of a lattice constant of the c-axis and a lattice constant of the a-axis matches the corresponding lattice constant of the c-axis and the a-axis of the hexagonal nitride semiconductor.

### BRIEF DESCRIPTION OF THE DRAWINGS

The above-described object and other objects, characteristics, and advantages of the present invention will be apparent from the detailed description of the embodiments of the present invention with reference to the accompanying drawings.

FIG. 1 is a schematic view of the structure of a group-III nitride semiconductor laser device and an epitaxial substrate according to an embodiment.

FIG. 2 is a table of various forms of cladding layers associated with lattice constants.

FIG. 3 is a drawing illustrating the wavelength dependence of the refractive index of a gallium nitride-based semiconductor (wavelength dispersion).

FIG. 4 illustrates a cathode luminescent (CL) image of an InGaN layer.

FIG. 5 is a drawing schematically showing the surface structures of a semiconductor semi-polar surface and a c-plane tilting at an angle larger than or equal to 63 degrees and smaller than 80 degrees.

FIG. 6 is a drawing illustrating the primary steps in a method of producing a nitride semiconductor laser device according to an embodiment.

FIG. 7 is a drawing illustrating the primary steps in a method of producing a nitride semiconductor laser device according to an embodiment.

FIG. 8 is a drawing showing schematic views of a group-III nitride semiconductor laser device according to Example 1.

FIG. 9 is a drawing which illustrates the relationship between the surface morphology and the growth plane orientation of InAlGaN.

FIG. 10 is a growing which illustrates a semiconductor laser device formed of an epitaxial substrate having a number of laser structures over the (20-21) GaN plane.

### DESCRIPTION OF THE PREFERRED EMBODIMENTS

The expertise of the invention can be easily understood through the detailed descriptions described below with reference to the accompanying drawings as an example. A nitride semiconductor laser device, an epitaxial substrate, and methods of fabricating an epitaxial substrate and a nitride semiconductor laser device according to embodiments of the present invention will now be described with reference to the accompanying drawings. The same elements will be designated by the same reference numerals, when appropriate.

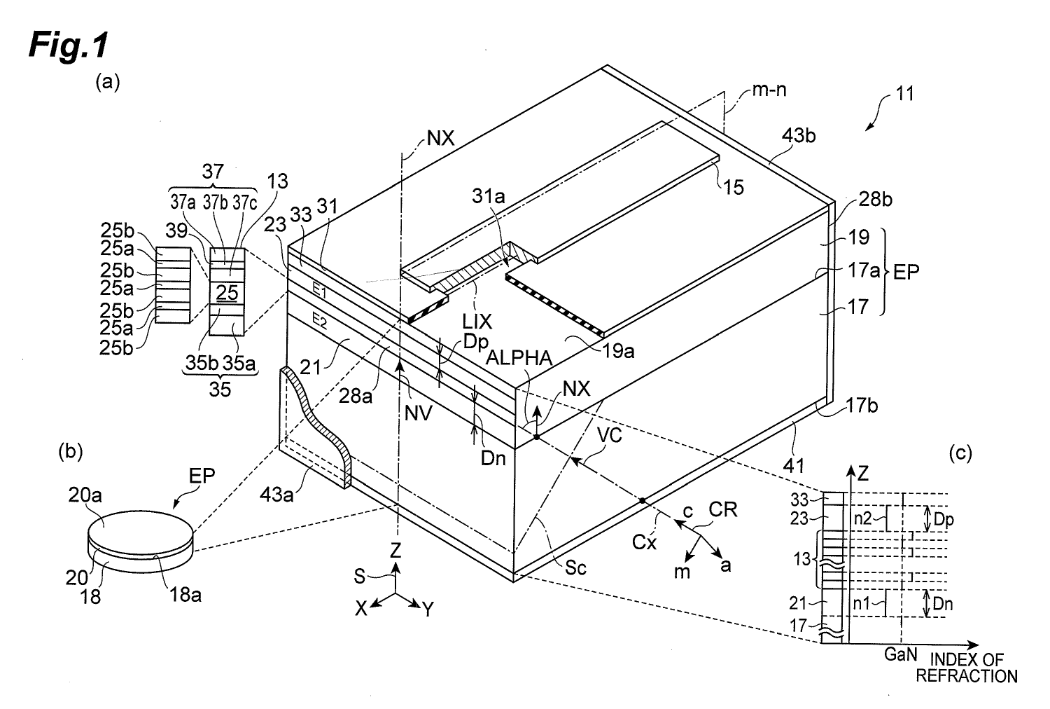

FIG. 1 is a schematic view of the structure of a group-III nitride semiconductor laser device and an epitaxial substrate according to this embodiment. The group-III nitride semiconductor laser device 11 has a gain-guided structure, as illustrated in part (a) of FIG. 1; however, the group-III nitride semiconductor laser device 11 according to an embodiment of the present invention is not limited to the specific ones of gain-guided structures and may instead have, for example, a ridge structure. The group-III nitride semiconductor laser device 11 includes a support base 17 and a semiconductor region 19. With reference to part (b) of FIG. 1, an epitaxial substrate EP of the group-III nitride semiconductor laser device 11 includes a substrate 18 in place of the support base 17, and a semiconductor layer 20 in place of the semiconductor region 19. The stack structure in the semiconductor layer 20 is the same as that of the semiconductor region 19. The front surface 20a of the semiconductor layer 20 of the epitaxial substrate EP has excellent surface morphology. The semiconductor layer 20 is provided over the semi-polar surface 18a of the substrate 18. The epitaxial substrate EP does not include any electrodes.

The group-III nitride semiconductor laser device 11 will now be described below. The description is also applicable to the epitaxial substrate EP for the nitride semiconductor laser device 11. The nitride semiconductor laser device 11 illustrated in part (a) of FIG. 1 includes an n-type cladding layer 21, a p-type cladding layer 23, and an active layer 25. The epitaxial substrate EP includes a first semiconductor layer, which corresponds to the n-type cladding layer 21, a second semiconductor layer, which corresponds to the p-type cladding layer 23, and a third semiconductor layer, which corresponds to the active layer 25. In the group-III nitride semiconductor laser device 11, the active layer 25 is included in a light-emitting layer 13, which is provided between the n-type cladding layer 21 and the p-type cladding layer 23. The light-emitting layer 13 functions as a core semiconductor region provided between the n-type cladding layer 21 and the p-type cladding layer 23. The semiconductor region 19 includes the light-emitting layer 13, the n-type cladding layer 21, and the p-type cladding layer 23.

The n-type cladding layer 21 is composed of a first nitride semiconductor containing indium and aluminum as group-III constituents. The p-type cladding layer 23 is composed of a second nitride semiconductor containing indium and aluminum as group-III constituents. The active layer 25 includes epitaxial layers composed of nitride semiconductor containing indium as a constituent. The active layer 25 emits light having a peak wavelength in the range of 480 to 600 nm. The refractive indices of the n-type cladding layer 21 and p-type cladding layer 23 are smaller than that of GaN. The thickness Dn of the n-type cladding layer 21 is 2 μm or more, and the thickness Dp of the p-type cladding layer 23 is 500 nm or more.

In the nitride semiconductor laser device 11, the n-type cladding layer 21, the p-type cladding layer 23, and the active layer 25 are provided over the support base 17. The support base 17 has, for example, an electric conductivity sufficient for current application to the nitride semiconductor laser device 11. The support base 17 has a front surface 17a and a back surface 17b, and the front surface 17a is made of semi-polar semiconductor surfaces. The front surface 17a is composed of a gallium nitride-based semiconductor, such as hexagonal GaN. In this embodiment, the support base 17 is composed of a hexagonal group-III nitride semiconductor or a gallium nitride-based semiconductor. The front surface 17a tilts from a reference plane, (for example, a typical c-plane Sc), which is orthogonal to a reference axis and extends along the c-axis (c-axis vector VC) of the gallium nitride-based semiconductor. The front surface 17a is semi-polar. The semiconductor region 19 is provided on the front surface 17a of the support base 17.

With reference to FIG. 1, an orthogonal coordinate system S and a crystal coordinate system CR are depicted. The normal axis NX extends along the Z-axis of the orthogonal coordinate system S. The front surface 17a extends parallel to a predetermined plane defined by the X- and Y-axes of the orthogonal coordinate system S. FIG. 1 also illustrates the typical c-plane Sc. In FIG. 1, the c-axis of the support base 17, which is composed of a group-III nitride semiconductor, tilts by an angle ALPHA from the normal axis NX toward the m-axis of the group-III nitride semiconductor.

The n-type cladding layer 21, the active layer 25, and the p-type cladding layer 23 are provided on the front surface 17a in this order. In the case of a support base 17 composed of a group-III nitride semiconductor, the group-III nitride semiconductor of the support base 17 defines the semi-polarity of the front surface 17a thereof. The n-type cladding layer 21, the active layer 25, and the p-type cladding layer 23 are provided over the front surface 17a in the direction of the normal axis NX. The front surface 17a tilts toward the m-axis of the hexagonal nitride semiconductor at an angle ALPHA that is larger than or equal to 63 degrees and smaller than 80 degrees from a plane orthogonal to the reference axis Cx that extends along the c-axis of the hexagonal nitride semiconductor. The active layer 25 is provided between the n-type cladding layer 21 and the p-type cladding layer 23.

In the nitride semiconductor laser device 11, the n-type cladding layer 21 is composed of a nitride semiconductor containing indium and aluminum as group-III constituents, while the p-type cladding layer 23 is composed of a nitride semiconductor containing indium and aluminum as group-III constituents. The growth temperature of AlN in the nitride semiconductor is quite different from that of InN. Hence, such a nitride semiconductor grows at a temperature lower than, for example, the growth temperature of GaN. The nitride semiconductor grown over the c-plane does not have satisfactory surface morphology due to an increase in thickness. It is also difficult to grow the n-type cladding layer 21 and the p-type cladding layer 23 with appropriate thicknesses because of the difference in growth temperature between AlN and InN. The quality of the surface morphology of these layers is not satisfactory.

The front surface 17a of the semi-polar semiconductor tilts by the angle ALPHA, which is within the range mentioned above. Step-flow growth of the nitride semiconductor occurs over the semi-polar surface inclined, at the low temperature mentioned above, which tilts at an angle within the above angle range. Thus, the n-type cladding layer 21 can be composed of a thick nitride semiconductor. The n-type cladding layer 21, which is composed of such a nitride semiconductor, has excellent surface morphology. Since the front surface of the n-type cladding layer 21 is a semi-polar surface with such excellent surface morphology, a core semiconductor region including the active layer 25 can be provided on the semi-polar surface. Consequently, the active layer 25 has excellent crystal quality. Hence, the active layer 25 has a semi-polar surface with excellent surface morphology. The surface of the core semiconductor region, i.e., the light-emitting layer 13, is semi-polar in the above angle range; hence, similar to the n-type cladding layer 21, the p-type cladding layer 23 provided over the active layer 25 can be composed of a thick nitride semiconductor. Accordingly, the n-type cladding layer 21 is composed of a thick first nitride semiconductor, and the p-type cladding layer 23 is composed of a thick second nitride semiconductor.

In the peak wavelength range of 480 to 600 nm of light that the active layer 25 emits, the difference in the refractive index between the cladding and the core is smaller than the refractive index difference in, for example, the wavelength range of blue light due to wavelength dispersion in the nitride semiconductor. In other words, this shows that the wavelength dispersion makes it difficult to enhance the difference in refractive index between nitride semiconductor materials and the refractive index difference cannot be used in order to enhance optical confinement.

The use of semi-polar surfaces having tilt angles within the angle range mentioned above can provide an n-type cladding layer 21 having a thickness of 2 μm or more and a p-type cladding layer 23 having a thickness of 500 nm or more. Consequently, a thick nitride semiconductor having a refractive index smaller than that of GaN compensates for a reduction in the difference between the indices of refraction due to wavelength dispersion.

In the nitride semiconductor laser device 11, the thickness of the n-type cladding layer 21 is preferably 3 μm or more. This can reduce leakage of light to the support base 17, stabilize the lasing mode of light, and thus reduce the driving current. The thickness of the p-type cladding layer 23 is preferably 1 μm or more. This can reduce leakage of light to the region adjacent to the electrode to reduce the loss in optical absorption and the driving current of the laser device.

The total thickness (Dn+Dp) of the n-type cladding layer 21 and the p-type cladding layer 23 is preferably 3 μm or more. A cladding layer having a total thickness (Dn+Dp) of 3 μm or more enables satisfactory optical confinement in the wavelength range of the light emitted from the active layer 25. This can reduce leakage of light to the support base to stabilize the lasing mode of light, and also reduce leakage of light toward the electrode to reduce the loss in optical absorption and the driving current of the laser device.

The thickness of the n-type cladding layer 21 may be larger than the thickness of the p-type cladding layer 23. The n-type cladding layer 21 is provided on the support base 17 of the group-III nitride semiconductor. The support base 17 may activate a substrate mode, so that the light propagates not in the core semiconductor region but in the substrate mode. The n-type cladding layer 21 having a thickness larger than the thickness of the p-type cladding layer 23 can however avoid generation of the substrate mode and thus improve the optical confinement.

The n-type cladding layer 21, the p-type cladding layer 23, and the active layer 25 are arrayed along the axis NX normal to the semi-polar front surface 17a. The active layer 25 includes epitaxial layers composed of gallium nitride-based semiconductors. The epitaxial layers are composed of ternary InGaN, which preferably has an indium content of 0.2 or more. Since the active layer 25 is provided on the semi-polar surface tilting at an angle that is larger than or equal to 63 degrees and smaller than 80 degrees, the technical contribution from the step-flow growth onto the semi-polar surface is also provided with the growth of InGaN. The active layer 25 may have a single quantum well structure or a multiple quantum well structure. The active layer 25 having a quantum well structure includes epitaxial layers that are, for example, well layers 25a. The active layer 25 also includes barrier layers 25b composed of a gallium nitride-based semiconductor. The well layers 25a and the barrier layers 25b are alternately arranged. The well layers 25a are composed of, for example, InGaN, and the barrier layers 25b are composed of, for example, GaN or InGaN. Since the active layer 25 is provided over a semi-polar surface, the nitride semiconductor laser device 11 is suitable for generating light having a wavelength in the range of 500 to 550 nm, leading to an excellent optical confinement and a small driving current within this wavelength range.

The semiconductor region 19 in the group-III nitride semiconductor laser device 11 includes a first end facet 28a and a second end facet 28b that intersect with the m-n plane defined by the m-axis and the normal axis NX of the hexagonal group-III nitride semiconductor. An electrode 15 is disposed on the semiconductor region 19, and an electrode 41 is disposed on the back surface 17b of the support base 17.

The group-III nitride semiconductor laser device 11 also includes an insulating layer 31. The insulating layer 31 covers the surface 19a of the semiconductor region 19. The insulating layer 31 has an opening 31a that has, for example, a strip shape extending along the intersecting line LIX of the m-n plane with the surface 19a of the semiconductor region 19. The electrode 15 is in contact with the surface 19a (for example, a second-conductivity-type contact layer 33) of the semiconductor region 19 through the opening 31a and extends along the intersecting line LIX. In the group-III nitride semiconductor laser device 11, the laser waveguide includes the n-type cladding layer 21, the p-type cladding layer 23 and the active layer 25 and extends along the intersecting line LIX.

As illustrated in FIG. 1, the p-type contact layer 33 forms a junction with the p-type cladding layer 23, and the electrode 15 forms a junction with the p-type contact layer 33. The p-type contact layer 33 may have a thickness of 300 nm or less and may have a thickness of 5 nm or more. The thickness of the p-type cladding layer 23 is greater than that of the p-type contact layer 33, which is required for establishing excellent contact with the electrode 15. The p-type contact layer 33 has a p-type dopant concentration preferably higher than the p-type dopant concentration of the p-type cladding layer 23. Such difference in concentration contributes to a reduction of the driving voltage because holes are supplied from the p-type contact layer 33 of a high dopant concentration to the p-type cladding layer 23 of a low dopant concentration. The refractive index of the p-type cladding layer 23 is preferably smaller than that of the p-type contact layer 33. The insulating layer 31 and the electrode 15 are provided on the p-type contact layer 33. The thick p-type cladding layer 23 prevents optical loss caused by absorption of the transmitted light by the electrodes.

In the group-III nitride semiconductor laser device 11, the first end facet 28a and the second end facet 28b intersect with the m-n plane, which is defined by the m-axis and the normal axis NX of the hexagonal group-III nitride semiconductor. The laser cavity of the group-III nitride semiconductor laser device 11 includes the end facets 28a and 28b, and the laser waveguide extends from one to the other of the end facets 28a and 28b. The end facets 28a and 28b differ from known cleaved surfaces, such as the c-plane, the m-plane, and the a-plane. In the group-III nitride semiconductor laser device 11, the end facets 28a and 28b, which constitute the laser cavity, intersect with the m-n plane. The laser waveguide extends along the intersecting line of the m-n plane and the front surface 17a. The group-III nitride semiconductor laser device 11 includes a laser cavity that operates on a low threshold current. Inter-band transition that enables low lasing threshold is selected for light generation at the active layer 25.

As illustrated in FIG. 1, a dielectric multilayer 43a is provided over the first end facet 28a, and a dielectric multilayer 43b is formed over the second end facet 28b. Coating is applied to the end facets 28a and 28b. Such coating can control the reflectance of the end facets.

The group-III nitride semiconductor laser device 11 includes an n-side optical guiding region 35 and a p-side optical guiding region 37. The n-side optical guiding region 35 may include at least one n-side optical guiding layer, and the p-side optical guiding region 37 may include at least one p-side optical guiding layer. The n-side optical guiding region 35 is composed of, for example, GaN or InGaN, and includes, for example, an n-side first optical guiding layer 35a and an n-side second optical guiding layer 35b. The p-side optical guiding region 37, which is composed of, for example, GaN or InGaN, includes a p-side first optical guiding layer 37a, a p-side second optical guiding layer 37b, and a p-side third optical guiding layer 37c. An electron blocking layer 39 is, for example, provided between the p-side first optical guiding layer 37a and the p-side second optical guiding layer 37b. The p-side third optical guiding layer 37c is provided between the electron blocking layer 39 and the active layer 25.

Specifically, the n-side first optical guiding layer 35a can serve as a first GaN optical guiding layer provided between the n-type cladding layer 21 and the active layer 25, while the n-side second optical guiding layer 35b can serve as a first InGaN optical guiding layer provided between the n-side first optical guiding layer 35a and the active layer 25. The p-side first optical guiding layer 37a may be composed of a second GaN optical guiding layer provided between the p-type cladding layer 23 and the active layer 25; the p-side second optical guiding layer 37b may be composed of a second InGaN optical guiding layer provided between the p-side first optical guiding layer 37a and the active layer 25; and the p-side third optical guiding layer 37c may be composed of a third InGaN optical guiding layer provided between the p-side second optical guiding layer 37b and the active layer 25. The optical guiding region 35 provided between the active layer 25 and the cladding layer 21, and the optical guiding region 37 provided between the active layer 25 and the cladding layer 23 include at least two layers (InGaN layer and GaN layer) of refractive indices different from each other, which can reduce internal strain and avoid a decrease in the difference in the refractive index between the cladding and the core.

In the nitride semiconductor laser device 11, the maximum value of the refractive index n_{core} of the light-emitting layer 13 (core semiconductor region) provided between the n-type cladding layer 21 and the p-type cladding layer 23 is preferably not less than (larger than or equal to) the refractive index of GaN. As illustrated in part (b) of FIG. 1, the thick n-type cladding layer 21 and p-type cladding layer 23 confines light in the core semiconductor region having a small refractive index. The n-type cladding layer 21 is composed of a single semiconductor layer and does not have a compositionally graded structure, in other words, has a single bandgap energy E1. The p-type cladding layer 23 is composed of a single semiconductor layer and does not have a compositionally graded structure, in other words, has a single bandgap energy E2. Accordingly, excellent optical confinement is established therein. The refractive index n1 of the first nitride semiconductor and the refractive index n2 of the second nitride semiconductor are smaller than the average refractive index of the core semiconductor region.

The electron blocking layer 39 is provided between the p-type cladding layer 23 and the active layer 25. It is preferable that the electron blocking layer 39 be provided between two InGaN layers with junction, when the front surface 17a of the semi-polar semiconductor is composed of GaN and the electron blocking layer 39 is composed of GaN. The electron blocking layer 39 composed of GaN can make alleviate the decrease in the effective refractive index of the core semiconductor region, which is provided between the cladding layers 21 and 23.

The front surface 17a of the semi-polar semiconductor may tilt from the reference axis Cx toward the m-axis by an angle of larger than or equal to 70 degrees and smaller than 80 degrees. Such tilting is preferable for providing an active layer that emits long-wavelength light. Segregation of indium in the light emitting layer is inhibited to improve the internal quantum efficiency.

In the nitride semiconductor laser device 11, the first nitride semiconductor of the n-type cladding layer 21 preferably contains gallium as a group-III constituent. The first nitride semiconductor may be composed of a material containing indium, aluminum, and gallium as group-III constituents. The second nitride semiconductor of the p-type cladding layer 23 preferably contains gallium as a group-III constituent. The second nitride semiconductor may be composed of a material containing indium, aluminum, and gallium as group-III constituents.

In the nitride semiconductor laser device 11, unlike AlGaN layers, indium contents of the n-type cladding layer 21 and the p-type cladding layer 23 which are not less than 0.01 enable adjustment in the lattice mismatch. Unlike InGaN layers, aluminum contents thereof which are not less than 0.03 make bandgap energy large and a refractive index small.

An indium content of 0.01 or more and an aluminum content of 0.03 or more in the n-type cladding layer 21 allows the adjustment of the lattice mismatch with respect to the support base while achieving excellent optical confinement due to the reduced refractive index. An indium content of 0.01 or more and an aluminum content of 0.03 or more in the p-type cladding layer 23 allows the adjustment of the lattice mismatch with respect to the support base while achieving excellent optical confinement due to the reduced refractive index.

In the n-type cladding layer 21 and p-type cladding layer 23 of the nitride semiconductor laser device 11 that are composed of InAlGaN, when the n-type cladding layer 21 and p-type cladding layer 23 have an indium content of 0.01 or more and an aluminum content of 0.03 or more enable the adjustment of the lattice mismatch with respect to the support base while achieving excellent optical confinement due to the reduction in the refractive index. Furthermore, a cladding layer containing gallium has crystal quality higher than that of a cladding layer not containing gallium. In the n-type cladding layer 21 and p-type cladding layer 23 that are composed of InAlN, the n-type cladding layer 21 and p-type cladding layer 23 has an indium contents of 0.01 or more and the n-type cladding layer 21 has an aluminum content of 0.03 or more, these cladding layers enable the adjustment of the lattice mismatch with respect to the support base while achieving excellent optical confinement due to the reduction in the refractive index. Furthermore, a cladding layer not containing gallium has smaller refractive index than that of a cladding layer containing gallium.

In the n-type cladding layer 21 that is composed of InAlGaN and p-type cladding layer 23 that is composed of MAIN, the n-type cladding layer contains gallium and thus the active layer on its layer has excellent crystal quality. In the n-type cladding layer 21 that is composed of InAlN and p-type cladding layer 23 that is composed of InAlGaN, the n-type cladding layer 21 has a small refractive index because it does not contain gallium; the leakage of light to the substrate is reduced; and the driving current of the laser device is reduced because the lasing mode is stabilized.

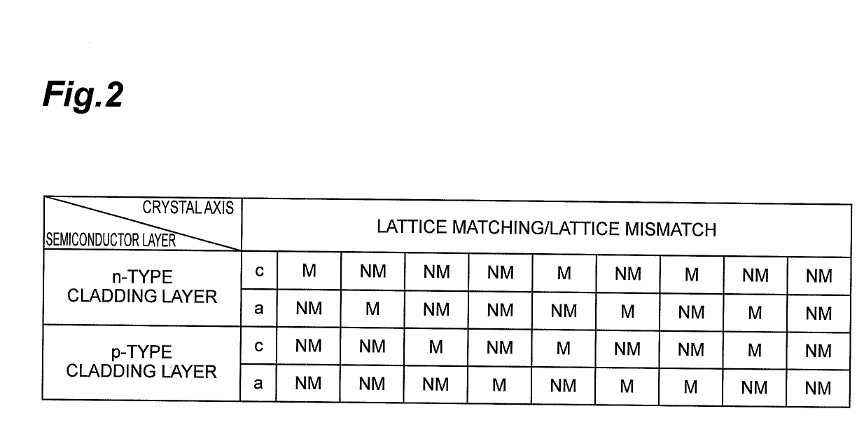

FIG. 2 illustrates a table of various forms of the cladding layer associated with lattice constants. In this table, “M” represents lattice matching, and “NM” represents lattice mismatch.

(Lattice Matching in a-Axis)

Preferably, the first nitride semiconductor of the n-type cladding layer 21 has indium and aluminum contents such that a lattice constant in the a-axis thereof matches the a-axis of the hexagonal group-III nitride semiconductor. The lattice mismatch R1a represented as R1a=(D1a-D0a)/D0a×100 satisfies −0.05≦R1a≦+0.05, using the definition of the lattice constant D1a of the a-axis of the first nitride semiconductor and the lattice constant D0a of the a-axis of the hexagonal group-III nitride semiconductor. Such lattice matching allows coherent epitaxial growth of a cladding layer having a thickness of 2 μm or more, without lattice relaxation.

(Lattice Matching in a-Axis)

Preferably, the second nitride semiconductor of the p-type cladding layer 23 has an indium and aluminum contents such that the a-axis of a lattice constant thereof matches the a-axis of the hexagonal group-III nitride semiconductor. The lattice mismatch R2a represented as R2a=(D2a-D0a)/D0a×100 satisfies −0.05≦R2a≦+0.05, using the definition of the lattice constant D2a of the a-axis of the second nitride semiconductor and the lattice constant D0a of the a-axis of the hexagonal group-III nitride semiconductor. Such lattice matching allows coherent epitaxial growth of a cladding layer having a thickness of 2 μm or more, without lattice relaxation.

(Lattice Matching in c-Axis)

Preferably, the first nitride semiconductor of the n-type cladding layer 21 has indium and aluminum contents such that the c-axis, which a lattice constant, matches the c-axis of the hexagonal group-III nitride semiconductor. The lattice mismatch R1c represented as R1c=(D1c-D0c)/D0c×100 satisfies −0.1≦R1c≦+0.1, using the definition of the lattice constant D1a of the c-axis of the first nitride semiconductor and the lattice constant D0c of the c-axis of the hexagonal group-III nitride semiconductor. Such lattice matching allows coherent epitaxial growth of a cladding layer having a thickness of 2 μm or more, without lattice relaxation.

(Lattice Matching in c-Axis)

Preferably, the second nitride semiconductor of the p-type cladding layer 23 has indium and aluminum contents such that the c-axis of a lattice constant thereof matches the c-axis of the hexagonal group-III nitride semiconductor. The lattice mismatch R2c represented as R2c=(D2c-D0c)/D0c×100 satisfies −0.1≦R2c≦+0.1, using the definition of the lattice constant D2c of the c-axis of the second nitride semiconductor and the lattice constant D0c of the c-axis of the hexagonal group-III nitride semiconductor is. Such lattice matching allows coherent epitaxial growth of a cladding layer having a thickness of 2 μm or more, without lattice relaxation.

(Lattice Mismatch in a-Axis)

The second nitride semiconductor of the p-type cladding layer 23 may have indium and aluminum contents such that the c-axis and the a-axis of lattice constants do not match the c-axis and the a-axis of the hexagonal group-III nitride semiconductor. Here, the relations, −0.15≦R2c≦+0.15 and −0.1≦R2a≦+0.1, are satisfied. The second nitride semiconductor is slightly strained, which is not zero, in the directions of the c-axis and the a-axis. This slight strain reduces lattice mismatch in association with the active layer 25 to lower the strain in the active layer 25, thereby improving the internal quantum efficiency.

(Lattice Mismatch of a-Axis and c-Axis)

Preferably, the first nitride semiconductor of the n-type cladding layer 21 has indium and aluminum contents such that the c-axis and the a-axis of lattice constants do not match the c-axis and the a-axis of the hexagonal group-III nitride semiconductor. Here, relations −0.45≦R1c≦+0.15 and −0.1≦R1a≦+0.25 are satisfied. The first nitride semiconductor is slightly strained in the directions of the c-axis and the a-axis. This slight strain reduces the lattice mismatch in the active layer 25 and reduces the strain in the active layer 25, improving the internal quantum efficiency.

(Lattice Mismatch of a-Axis and c-Axis)

Preferably, the second nitride semiconductor of the p-type cladding layer 23 has indium and aluminum contents such that one of the c-axis and the a-axis of the first lattice constant matches the lattice constant of the hexagonal nitride semiconductor, while the first nitride semiconductor of the n-type cladding layer 21 has indium and aluminum contents such that the other of c-axis and a-axis of the second lattice constant matches corresponding lattice constant of one of c-axis and a-axis of the hexagonal nitride semiconductor. The first nitride semiconductor has lattice matching in the direction of, for example, the c-axis (or a-axis). The second nitride semiconductor has lattice matching in the direction of, for example, the a-axis (and c-axis).

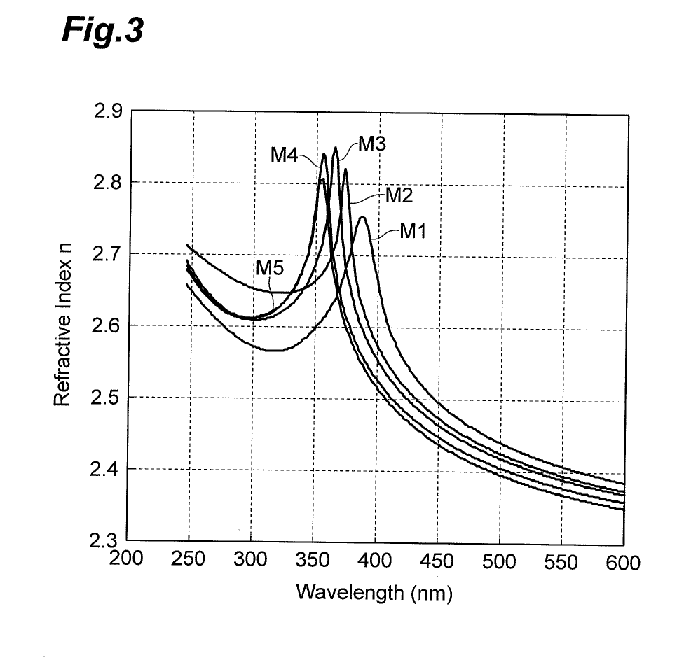

FIG. 3 illustrates the wavelength dependence of the refractive index of a gallium nitride-based semiconductor (wavelength dispersion). In FIG. 3, symbol M1 represents InGaN (indium content: 0.06), symbol M2 represents InGaN (indium content: 0.02), symbol M3 represents GaN, symbol M4 represents AlGaN, and symbol M5 represents InAlGaN. When the active layer 25 emits light of an emission spectrum containing a single peak wavelength in the range of 480 to 600 nm, decreases in the difference in the refractive index among different materials causes increase in the wavelength.

One technical problem in design matter on the structure of a long-wavelength semiconductor laser device is to provide a practical solution to the following technical issue. That is, the difference in the refractive index of GaN, AlGaN, and InGaN decreases as the wavelength increases, resulting in a reduction in optical confinement.

The cladding layer provided between the substrate and the active layer in order to prevent a reduction in optical confinement cannot readily increase the refractive index difference for optical confinement because of the effect of the substrate adjoining the cladding layer and having a larger thickness than the cladding layer. When the difference in the refractive index cannot be made large because of the action of the substrate, the propagating light has a relatively large amplitude in the substrate. In order to make the amplitude small, a cladding layer having, for example, a large thickness, is used. The cladding layer that is provided between the active layer and the electrode on the surface of the epitaxial substrate has a larger refractive index difference, which is associated with optical confinement, as compared to the n-side region because the outer side of the epitaxial substrate is not a semiconductor. The electrode on the epitaxial substrate, however, reflects and absorbs the propagating light, causing an increase in transmission loss. A thick cladding layer is provided, for example, to prevent an increase in this optical loss. A thick cladding layer, however, may cause a reduction in its crystal quality, resulting in an adverse effect on the light emitting layer.

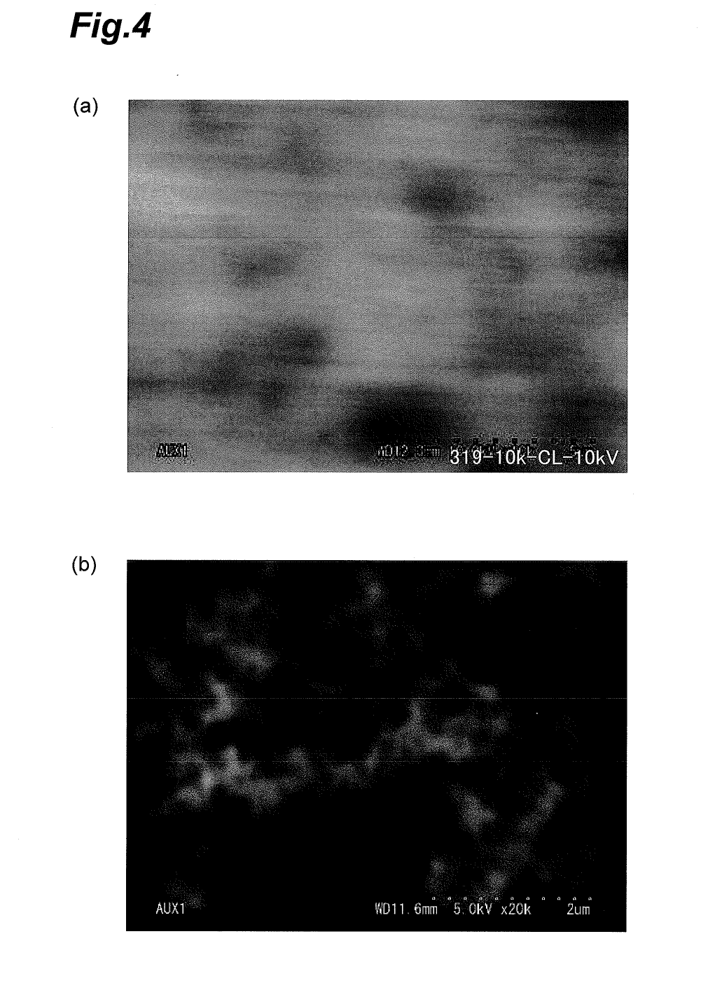

In the production of long-wavelength nitride gallium-based light-emitting devices, a technical problem is an improvement in the quality of the light emitting layer. The causes for the problem are as follows: a piezoelectric field in the active layer; and inhomogeneous indium composition in the active layer. FIG. 4 illustrates a cathode luminescent (CL) image of the InGaN layer. With reference to part (a) of FIG. 4, the CL image of InGaN (indium content: 0.25) is shown, which is provided over a semi-polar surface (surface displaced by 75 degrees toward the m-axis) having a tilt angle of larger than or equal to 63 degrees and smaller than 80 degrees. This CL image shows homogeneous light emission. Such homogeneity in light is achieved by a homogeneous indium composition. With reference to part (b) of FIG. 4, a CL image of InGaN (indium content of 0.25) is shown, which is provided over the c-plane. This CL image shows that the emitted light is inhomogeneous as compared with that of the CL image illustrated in part (a) of FIG. 4. Emission of such inhomogeneous light is caused by an inhomogeneous indium content. The c-plane is unsuitable for growing a gallium nitride-based semiconductor having a high and homogeneous indium content.

The cladding layer of a gallium nitride-based semiconductor laser device is typically composed of AlGaN. But, a lattice mismatch between AlGaN and GaN is large and a thick AlGaN layer increases strain of the epitaxial layer in the active layer, resulting in a reduction in light emission efficiency. A significantly large lattice mismatch may cause cracking in the AlGaN layer.

The technical issue involving constituents provided over the c-plane apply not only to the InGaN layer, which corresponds to the active layer, but also to the cladding layer that is composed of a nitride semiconductor containing aluminum and indium. Unlike AlGaN, a nitride semiconductor containing aluminum, which has a small atomic radius, and indium, which has a large atomic radius, is advantageous in controlling the lattice constants thereof. The growth temperatures of AlN and InN in the nitride semiconductor and the growth temperature of GaN are listed below:

Material, Optimal growth temperature.
AlN., 1100 degrees Celsius to 1200 degrees Celsius;
GaN, 1000 degrees Celsius to 1100 degrees Celsius; and
InN, 500 degrees Celsius to 600 degrees Celsius.
As listed above, the cladding layer is preferably composed of a nitride semiconductor containing aluminum and indium, such as InAlGaN. However, since difference in the optimal growth temperature between AlN (and GaN) and InN is significant, it is not easy to grow a thick InAlGaN layer. The difficulty in the growth of a thick InAlGaN layer increases with the indium content. This is because indium can be incorporated into InAlGaN only at a low growth temperature.

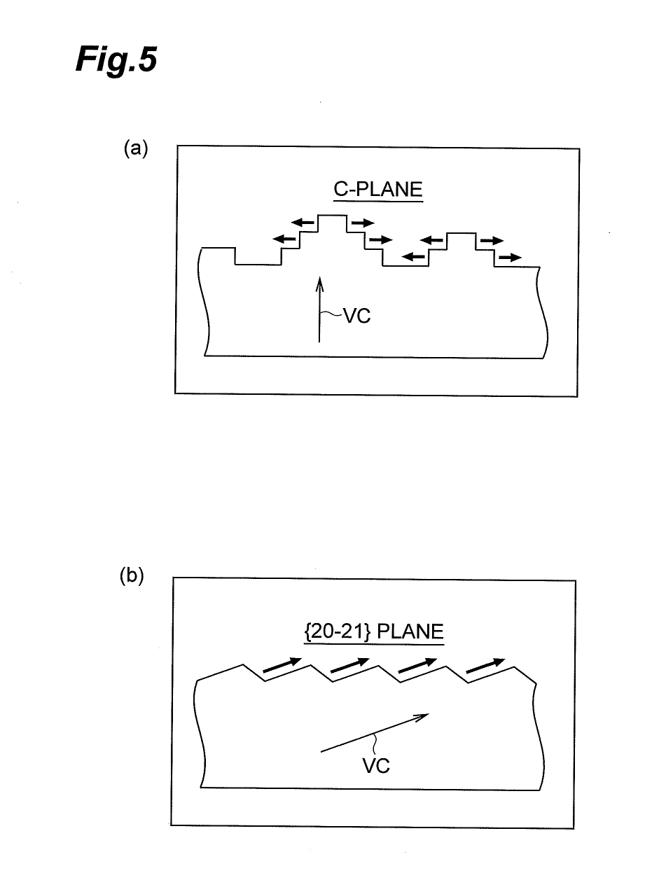

The inventors have discovered that the surface structure of a semiconductor semi-polar surface tilting by an angle of not less than 63 degrees and smaller than 80 degrees is suitable for growth of a nitride semiconductor containing aluminum and indium. FIG. 5 is a schematic view showing the surface structures of a semiconductor semi-polar surface and a c-plane tilting at an angle of not less than 63 degrees and smaller than 80 degrees. Referring to part (a) of FIG. 5, a growth mode referred to as “Island-like Growth” is the dominant growth mode in which InAlGaN having a desired indium content grows on the c-plane at low temperature. The size of the crystal islands is within the range of several tens of nanometers to several hundred nanometers. Consequently, the surface morphology is made unsatisfactory.

Referring to part (b) of FIG. 5, a growth mode referred to as “Step-Flow Growth” is the dominant growth mode in which InAlGaN having a desired indium content grows on the semiconductor semi-polar surface at low temperature. The size of the steps on the semi-polar semiconductor surface is approximately several nanometers. Consequently, the surface morphology is made satisfactory. This also assures both a homogeneous distribution of constituents and thick growth. The crystalline semi-polar surface comprises microscopic steps, and step-flow growth occurs at low temperature, resulting in high quality crystal.

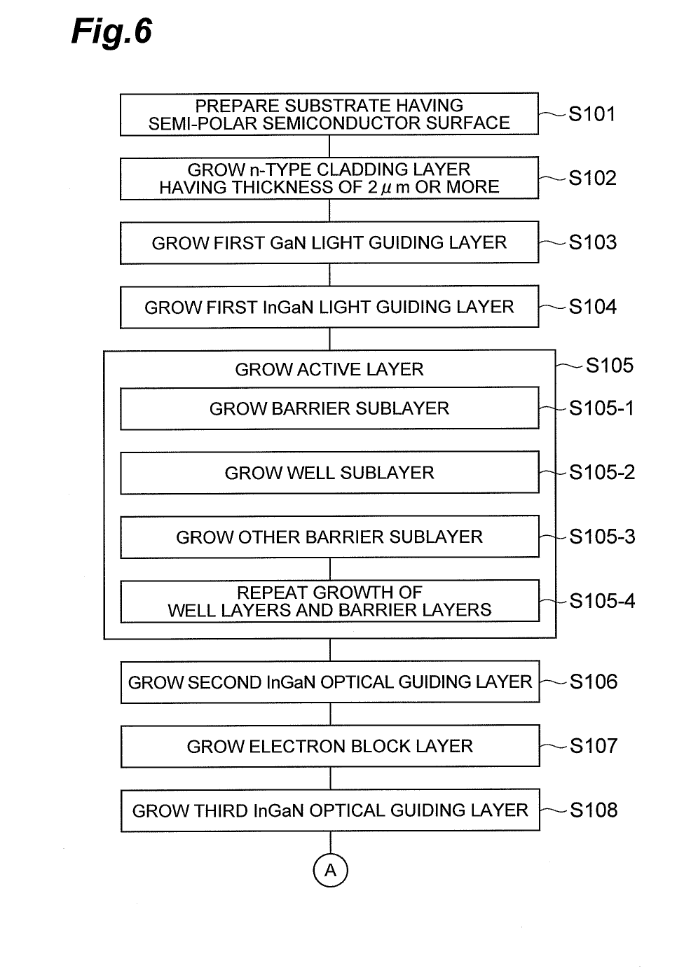

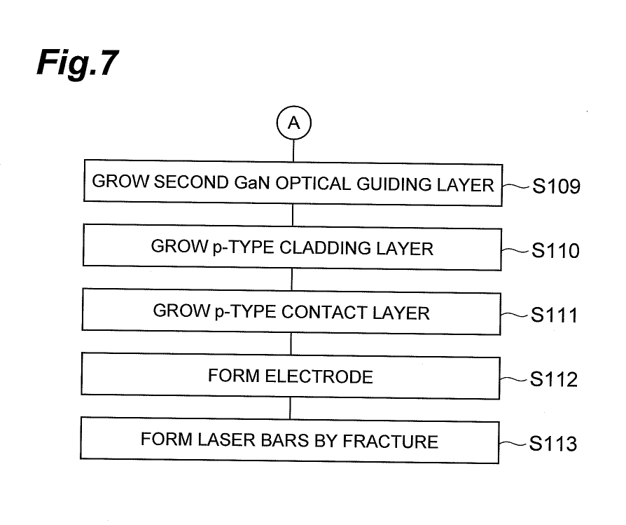

FIGS. 6 and 7 illustrate the primary steps in a method of fabricating a nitride semiconductor laser device according to this embodiment. The method of fabricating a nitride semiconductor laser device will now be described with reference to FIGS. 6 and 7. A laser diode is grown by metal organic chemical vapor growth, as described in the examples below. The materials used include trimethylgallium (TMGa), trimethylaluminium (TMAl), trimethylindium (TMIn), ammonium (NH₃), silane (SiH₄), and Bis(cyclopentadienyl)magnesium (Cp₂Mg). In Step S101, a substrate comprising a hexagonal nitride semiconductor and having a semi-polar semiconductor surface is prepared. The semi-polar semiconductor surface is inclined toward the m-axis of the hexagonal nitride semiconductor at an angle of not less than 63 degrees and smaller than 80 degrees from a plane orthogonal to the reference axis extending along the c-axis of the hexagonal nitride semiconductor. In this example, the substrate corresponds to a gallium nitride-based semiconductor substrate, such as a GaN substrate. The front surface of the GaN substrate may is inclined at an angle of 75 degrees toward the m-axis of GaN away from a plane orthogonal to the reference axis extending along the c-axis of the GaN semiconductor.

In Step S102, an n-type cladding layer having a thickness of 2 μm or more is grown on the semi-polar semiconductor surface of the substrate. The refractive index of the n-type cladding layer is smaller than that of GaN. The n-type cladding layer may be composed of a first nitride semiconductor containing indium and aluminum as group-III constituents, such as Si-doped InAlGaN or Si-doped InAlN. The front surface of the n-type cladding layer has semi-polarity that is similar to the semi-polarity of the semi-polar semiconductor surface of the substrate. The growth temperature may be within the range of 800 degrees Celsius to 950 degrees Celsius. In this example, the growth temperature is 870 degrees Celsius. If necessary, an n-type buffer layer may be grown on the semi-polar semiconductor surface of the substrate before growing the n-type cladding layer. The n-type buffer layer is composed of, for example, the same materials as those of the semi-polar semiconductor surface.

In Step S103, after the n-type cladding layer is grown, a first GaN optical guiding layer is grown over the front surface of the n-type cladding layer. The first GaN optical guiding layer has a thickness in the range of, for example, 50 to 500 nm. The front surface of the first GaN optical guiding layer has semi-polarity which is similar to the semi-polarity of the semi-polar semiconductor surface of the substrate. The growth temperature may be within the range of 800 degrees Celsius to 1100 degrees Celsius. In this example, the growth temperature is 1050 degrees Celsius.

In Step S104, after growing the first GaN optical guiding layer, a first InGaN optical guiding layer is grown on the front surface of the first GaN optical guiding layer. The first InGaN optical guiding layer has a thickness within the range of, for example, 50 to 250 nm. The front surface of the first InGaN optical guiding layer has semi-polarity which is similar to the semi-polarity of the semi-polar semiconductor surface of the substrate. The indium content of the first InGaN optical guiding layer is within the range of, for example 0.01 to 0.05. The growth temperature may be higher than or equal to 800 degrees Celsius and lower than 900 degrees Celsius. In this example, the growth temperature is 840 degrees Celsius.

In Step S105, after growing the optical guiding layers, an active layer is grown over the semi-polar semiconductor surface. The active layer can emit light having a peak wavelength within the range of 480 to 600 nm. The active layer has, for example, a single quantum well structure, a multiple quantum well structure, or a bulk structure. The growth of an active layer having a single quantum well structure may comprise growing an optical guiding layer and then growing a well layer on the semi-polar semiconductor surface. Alternatively, the growth of an active layer may comprise growing the optical guiding layers, growing a barrier layer on the semi-polar semiconductor surface in Step S105-1, and then growing a well layer on the barrier layer in Step S105-2. In Step S105-3, another barrier layer can be grown on the well layer. If required, well layers and barrier layers can be alternately grown in Step S105-4. The well layer is composed of, for example, InGaN, and the barrier layer is composed of, for example, GaN or InGaN. The growth temperature of the well layer is preferably 800 degrees Celsius or lower, for example, so that the indium content reaches 0.20 or more during the semiconductor growth of the active layer. The growth temperature of the barrier layer is preferably 900 degrees Celsius or lower, for example, so as to prevent thermal damage of the well layer during the semiconductor growth of the active layer. The indium content in the InGaN well layer is 0.2 or more. The front surface of the active layer has semi-polarity similar to the semi-polarity of the semi-polar semiconductor surface of the substrate. The growth temperature of the well layer may be less than 670 degrees Celsius and not more than 780 degrees Celsius. In this example, In_{0.30}Ga_{0.70}N is grown at 720 degrees Celsius. The growth temperature of the well layer and the barrier layer is preferably 900 degrees Celsius or lower, for example, so as to prevent thermal damage of the well layer during the semiconductor growth of the active layer.

In Step S106, after growing the active layer, a second InGaN optical guiding layer is grown on the front surface of the active layer. The second InGaN optical guiding layer has a thickness within the range of, for example, 50 to 100 nm. The indium content of the second InGaN optical guiding layer is within the range of, for example, 0.01 to 0.05. The front surface of the second InGaN optical guiding layer has semi-polarity similar to the semi-polarity of the semi-polar semiconductor surface of the substrate. The growth temperature may be within the range of 800 degrees Celsius to 900 degrees Celsius. In this example, the growth temperature is 840 degrees Celsius.

In Step S107, after growing the second InGaN optical guiding layer, an electron blocking layer is grown thereon. The electron blocking layer is preferably composed of GaN to reduce the growth temperature of the electron blocking layer compared with that of AlGaN. The front surface of the electron blocking layer has semi-polarity similar to the semi-polarity of the semi-polar semiconductor surface of the substrate. The growth temperature may be within the range of 800 degrees Celsius to 900 degrees Celsius. In this example, the growth temperature is 900 degrees Celsius.

In Step S108, after growing the electron blocking layer, a third InGaN optical guiding layer is grown on the front surface of the electron block layer. The third InGaN optical guiding layer has a thickness within the range of, for example, 50 to 250 nm. The indium content in the third InGaN optical guiding layer is within the range of, for example, 0.01 to 0.05. The front surface of the third InGaN optical guiding layer has semi-polarity similar to the semi-polarity of the semi-polar semiconductor surface of the substrate. The electron blocking layer is provided between the two InGaN layers with junctions. The growth temperature may be within the range of 800 degrees Celsius to 900 degrees Celsius. In this example, the growth temperature is 840 degrees Celsius.

In Step S109, after growing the third InGaN optical guiding layer, a second GaN optical guiding layer is grown on the front surface of the third InGaN optical guiding layer. The second GaN optical guiding layer may be doped with magnesium. The second GaN optical guiding layer has a thickness within the range of, for example, 50 to 500 nm. The front surface of the second GaN optical guiding layer has semi-polarity similar to the semi-polarity of the semi-polar semiconductor surface of the substrate. The growth temperature may be within the range of 800 degrees Celsius to 950 degrees Celsius. In this example, the growth temperature is 840 degrees Celsius.

In Step S110, after growing the optical guiding layer, a p-type cladding layer having a thickness of 500 nm or more is grown on the semi-polar semiconductor surface. The refractive index of the p-type cladding layer is smaller than that of GaN. The p-type cladding layer is composed of a second nitride semiconductor containing indium and aluminum as group-III constituents. The second nitride semiconductor is, for example, Mg-doped InAlGaN or Mg-doped InAlN. The front surface of the p-type cladding layer has semi-polarity, which is similar to that of the semi-polar semiconductor surface of the substrate. The growth temperature may be within the range of 800 degrees Celsius to 950 degrees Celsius. In this example, the growth temperature is 870 degrees Celsius.

In Step S111, after growing the p-type cladding layer, a p-type contact layer is grown on the front surface of the p-type cladding layer. The front surface of the p-type contact layer has semi-polarity, which is similar to the semi-polarity of the semi-polar semiconductor surface of the substrate. The p-type contact layer is composed of, for example, Mg-doped GaN. The growth temperature may be within the range of 800 degrees Celsius to 950 degrees Celsius. In this example, the growth temperature is 900 degrees Celsius.

An epitaxial substrate is produced through such procedures.

In Step S112, a substrate product is obtained by disposing an anode on the p-type contact layer while disposing a cathode on the back side of the substrate. In Step S113, the substrate product is cut into laser bars, each of which has a length corresponding to the laser cavity.

Through such a production process, the n-type cladding layer of the nitride semiconductor laser device is composed of a nitride semiconductor containing indium and aluminum as group-III constituents while the p-type cladding layer is composed of a nitride semiconductor containing indium and aluminum as group-III constituents. The growth temperature of AlN in the nitride semiconductors is quite different from the growth temperature of InN. Thus, the nitride semiconductors are grown at a temperature which is lower than the growth temperature of GaN, for example. The nitride semiconductor grown on the c-plane does not have satisfactory surface morphology due to an increase in thickness. Thick n-type and p-type cladding layers cannot be readily grown due to a difference in the growth temperature between AlN and InN. Hence, satisfactory surface morphology is not acquired therein.

The refractive index difference between the cladding and the core is small for light emitted from the active layer having a peak wavelength within the range of 480 to 600 nm, because the nitride semiconductor has significant wavelength dispersion. The difference of the refractive index is smaller than, for example, the wavelength range of blue light. In other words, the enhancement of optical confinement cannot be obtained by the difference of the refractive index between nitride semiconductor materials.

The nitride semiconductor grown at a low temperature through step-flow growth on a semi-polar surface tilting at an angle of not less than 63 degrees and smaller than 80 degrees enables the production of a thick nitride semiconductor applicable for the n-type cladding layer. Such a nitride semiconductor also has satisfactory surface morphology. A core semiconductor region having an active layer can be grown on the semi-polar surface having such satisfactory surface morphology, and the active layer grown has excellent crystal quality. The semi-polarity of the surface of the core semiconductor region tilting within the above-mentioned angle range permits the growth of a thick nitride semiconductor as a p-type cladding layer for same reason as the growth of a thick n-type cladding layer.

A semi-polar surface tilting within the above-mentioned range technically contributes to the growth of an n-type cladding layer having a thickness of 2 μm or more and a p-type cladding layer having a thickness of 500 nm or more. Accordingly, the thick nitride semiconductors having a refractive index smaller than that of GaN can compensate for a reduction in the difference of the refractive index because of wavelength dispersion. An n-type cladding layer having a thickness of 2 μm or more makes the leakage of light to the support base small, stabilizes the lasing mode, and decreases the driving current. A p-type cladding layer having a thickness of 500 nm or more makes the leakage of light to the electrode small, reduces optical loss due to absorption, and decreases the driving current of the laser device.

In the production process described above, a GaN optical guiding layer is preferably grown on the n-type cladding layer at a temperature of 1000 degrees Celsius or higher. Preferably, the growth temperature of the n-type cladding layer is 950 degrees Celsius or lower; the growth temperature of the active layer is 900 degrees Celsius or lower; and the semi-polar semiconductor surface is composed of GaN. In this production process, the growth temperature of the GaN semiconductor layer is 1000 degrees Celsius or higher, which is higher than the growth temperatures of other semiconductor layers; thus, a GaN layer having excellent crystal quality can be grown before growth of an active layer that generates long-wavelength light.

In the production process described above, before growth of the active layer, the n-type cladding layer and the InGaN optical guiding layer are grown at a preferable growth temperature of 950 degrees Celsius or lower, for example, to create satisfactory surface morphology.

In the production process, the growth temperature is preferably 950 degrees Celsius or lower after growth of the active layer until completing the growth of the p-type cladding layer. A growth temperature of 950 degrees Celsius or lower reduces thermal stress applied to the InGaN layer with a high indium content of the active layer that generates light of a long-wavelength.

### Example 1

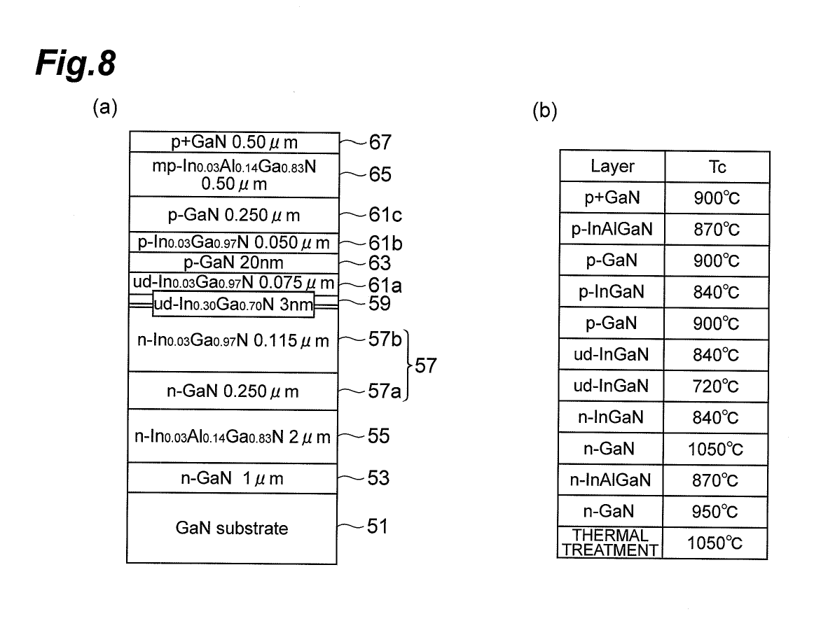

FIG. 8 is a schematic view showing a group-III nitride semiconductor laser device according to Example 1. Part (a) of FIG. 8 is a schematic view showing the structure of the group-III nitride semiconductor laser device. Such a group-III nitride semiconductor laser device is produced under the process conditions listed in part (b) of FIG. 8.

A group-III nitride substrate is prepared which has a semi-polar front surface. In this example, a GaN substrate 51 which is prepared has a semi-polar front surface tilting toward the m-axis at an angle of 75 degrees. The plane orientation of the semi-polar front surface corresponds to the {20-21} plane. A semiconductor region having an LD structure LD1 operable in a lasing wavelength band of 520 nm is grown on the semi-polar front surface of the GaN substrate 51. The GaN substrate 51 is placed in a growth reactor for pre-processing (thermal cleaning). Such pre-processing is performed in an ammonia and hydrogen atmosphere for ten minutes at 1050 degrees Celsius.

After the pre-processing, a gallium nitride-based semiconductor layer, such as an n-type gallium nitride layer 53, is grown over the GaN substrate 51 at a growth temperature of 950 degrees Celsius. The n-type GaN layer has a thickness of, for example, 1000 nm. An n-type cladding layer is grown on the gallium nitride-based semiconductor layer. The n-type cladding layer 55 has, for example, an InAlGaN layer (indium content of 0.03, aluminum content of 0.14, and gallium content of 0.83) grown at a growth temperature of 870 degrees Celsius. The n-type cladding layer 55 has a thickness of, for example, 2 μm. The n-type InAlGaN layer incorporates internal strain. An n-side optical guiding layer having a thickness of 2 μm or more is grown on the n-type cladding layer 55. In this example, the n-side optical guiding layer has, for example, an n-type GaN layer 57a grown at a growth temperature of 1050 degrees Celsius and an undoped InGaN layer 57b grown at a growth temperature of 840 degrees Celsius. The InGaN layer 57b has a thickness of, for example, 115 nm. The n-type GaN layer 57a has a thickness of, for example, 250 nm.

An active layer is grown on the n-side optical guiding layer 57. The active layer 59 includes a well layer. In this example, the well layer has, for example, an In_{0.3}Ga_{0.7}N sub-layer (indium content of 0.30 and gallium content of 0.70) that is grown at a temperature of 720 degrees Celsius and that has a thickness of, for example, 3 nm. The InGaN layer has internal compression stress. If necessary, the active layer 59 may have, for example, a barrier layer that has, for example, a GaN layer that is grown at a growth temperature of 840 degrees Celsius and that has a thickness of, for example, 15 nm.

A first p-side optical guiding layer and an electron blocking layer are grown on the active layer 59. In this example, the first p-side optical guiding layer has, for example, an undoped InGaN layer 61a grown at a growth temperature of 840 degrees Celsius. The p-side InGaN layer 61a has a thickness of, for example, 75 nm. The p-side InGaN layer 61a has internal strain. The electron blocking layer is then grown on the first p-side optical guiding layer. In this example, the electron blocking layer has, for example, a p-type GaN layer 63 grown at a growth temperature of 900 degrees Celsius. The GaN layer 63 has a thickness of, for example, 20 nm. A second p-side optical guiding layer is grown on the electron blocking layer. The second p-side optical guiding layer has, for example, a p-type InGaN layer 61b grown at a growth temperature of 840 degrees Celsius. The p-type InGaN layer 61b has a thickness of, for example, 50 nm. A third p-side optical guiding layer is grown on the second p-side optical guiding layer. The third p-side optical guiding layer has, for example, a p-type GaN layer 61c grown at a growth temperature of 900 degrees Celsius. The p-type GaN layer 61c has a thickness of, for example, 250 nm.

A p-type cladding layer is grown over the third p-side optical guiding layer. The p-type cladding layer has, for example, an InAlGaN layer 65 (indium content of 0.03, aluminum content of 0.14, and gallium content of 0.83) grown at a growth temperature of 870 degrees Celsius. The p-type cladding layer has a thickness of, for example, 0.50 μm. A p-type InAlGaN layer 65 has internal strain. The lattice mismatch of InAlGaN of the p-type cladding layer with respect to GaN is 0.01% or lower (absolute value) for the a-axis and −0.25% for the c-axis.

A p-type contact layer is grown on the p-type cladding layer. In this example, the p-type contact layer has, for example, a GaN layer grown at a growth temperature of 900 degrees Celsius. The p-type contact layer has a thickness of, for example, 50 nm. The epitaxial substrate is formed through the procedures described above.

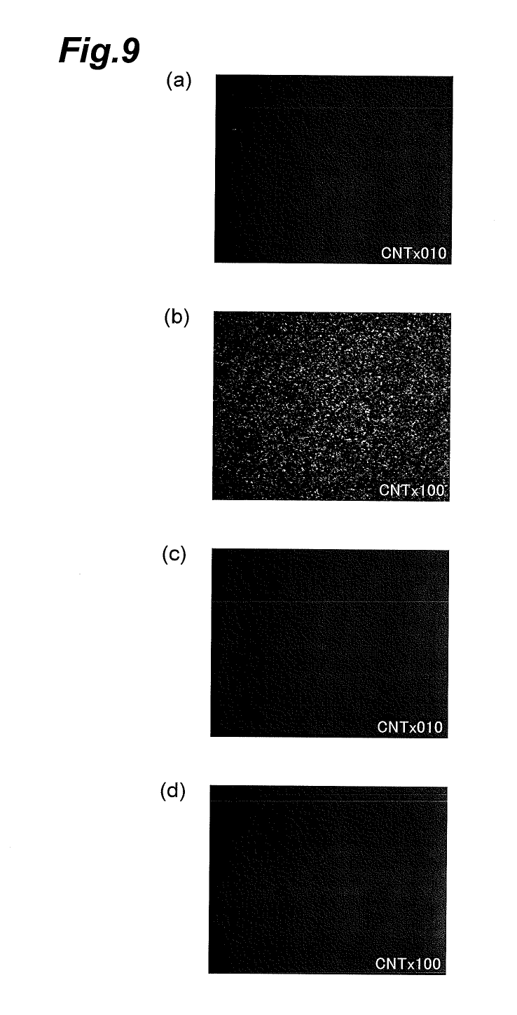

FIG. 9 is a drawing illustrating the relationship between the surface morphology and the growth plane orientation of InAlGaN. The Nomarski microscope images in FIG. 9 show the surface morphology of InAlGaN layers grown simultaneously on the (20-21) GaN plane and the (0001) GaN plane through the procedures described above. In parts (a) and (b) of FIG. 9, the aluminum content and indium content in the InAlGaN layer on the (0001) GaN plane are 0.14 and 0.03, respectively. In parts (c) and (d) of FIG. 9, the aluminum content and indium content of the InAlGaN layer on the (20-21) GaN plane are 0.14 and 0.03, respectively. The surface morphology of the InAlGaN layer on the (20-21) GaN plane is more satisfactory than the surface morphology of the InAlGaN layer on the (0001) GaN plane. The surface morphology of the InAlGaN layer on the (20-21) GaN plane, which is illustrated in parts (c) and (d) of FIG. 9, corresponds to a flat mirror epitaxial surface. The InAlGaN layer on the (0001) GaN plane, illustrated in parts (a) and (b) of FIG. 9, does not have a mirror epitaxial surface due to roughness. Thus, a semiconductor laser device produced through the production process does not lase.

### Example 2

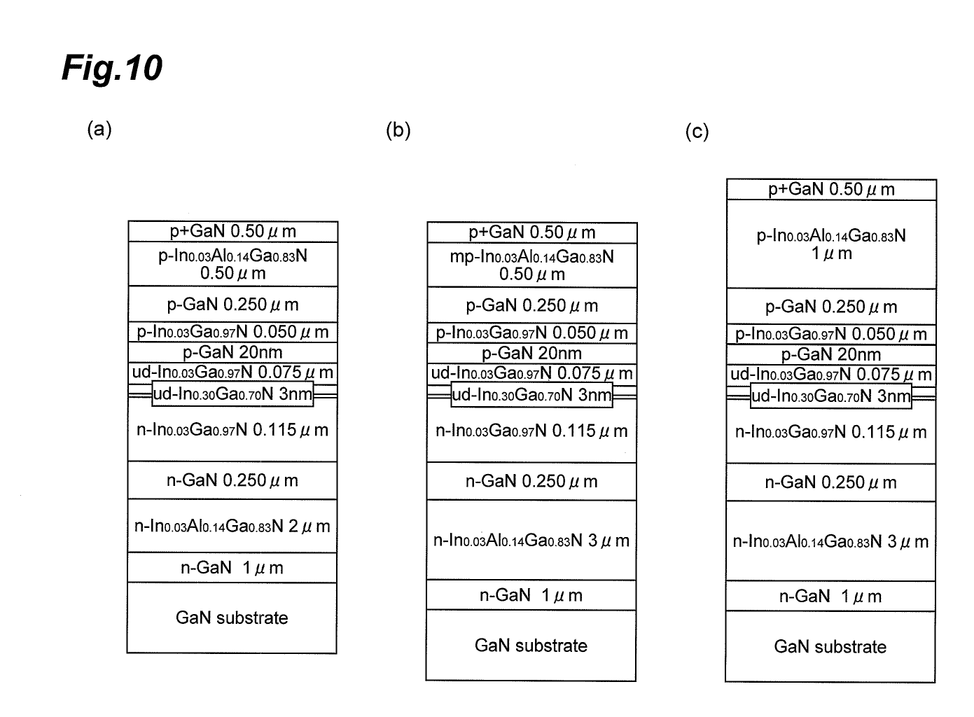

FIG. 10 is a drawing illustrating the structure of a semiconductor laser device composed of an epitaxial substrate having several laser structures formed on the (20-21) GaN plane. Several laser epitaxial structures are grown on the (20-21) GaN plane under growth conditions that are the same as those in Example 1 except for the thickness of the cladding layer. The laser epitaxial structure illustrated in part (a) of FIG. 10 is the same as the structure in Example 1. Referring to part (b) of FIG. 10, the n-type cladding layer has a large thickness. Referring to part (c) of FIG. 10, the n-type and p-type cladding layers have a large thickness.

An epitaxial substrate having such a laser epitaxial structure is made through a laser production process, such as that described below. An insulating layer, such as a silicon dioxide layer, is grown on the laser epitaxial structure. Then, wet-etching is applied to the insulating layer in order to form a window of a strip shape with a width of 10 μm to form a protective layer. An anode composed of palladium is formed and a pad electrode is formed on the anode. A cathode composed of palladium is formed on the back surface of the GaN substrate, and a pad electrode is formed on the cathode. A substrate product is obtained through such a process. The substrate product is cut every 600 μm into laser bars. Such fractured surfaces formed as above are substantially orthogonal to the {20-21} plane and the {21-20} plane. Each laser bar constitutes a laser cavity through the growth of dielectric multilayers on the fractured surfaces of the laser bar. Each dielectric multilayer is composed of, for example, a SiO₂/TiO₂ multiplayer. The reflectance of the front end facet is set to 80% while the rear end facet is set to 95%.

The three different types of semiconductor laser devices are energized to lase at the same wavelength of 525 nm. The threshold current densities of these semiconductor laser devices are listed below:

The laser epitaxial structure illustrated in part (a) of FIG. 10: 5×10³ A/cm²;
The laser epitaxial structure illustrated in part (b) of FIG. 10: 4×10³ A/cm²; and
The laser epitaxial structure illustrated in part (c) of FIG. 10: 3×10³ A/cm²

These threshold current densities indicate that a nitride semiconductor laser device including a thick cladding layer has a small threshold current for generating long-wavelength light. The present embodiments provide practical laser structures for a semiconductor laser device generating light of a wavelength in the range of 480 to 600 mm, enabling reduction in the threshold current.

As described above, the present embodiments provide a nitride semiconductor laser device that has a cladding structure suitable for long-wavelength lasing. The present embodiments also provide an epitaxial substrate for such a nitride semiconductor laser device. Furthermore, the present embodiments provide a method of fabricating a nitride semiconductor laser device.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A nitride semiconductor laser device comprising:
an n-type cladding layer comprising a first nitride semiconductor, the first nitride semiconductor comprising indium and aluminum as group-III constituents;
an active layer having an epitaxial layer, the epitaxial layer comprising a nitride semiconductor, the nitride semiconductor comprising indium as a group-III constituent;
a p-type cladding layer comprising a second nitride semiconductor, the second nitride semiconductor comprising indium and aluminum as group-III constituents,
the n-type cladding layer, the active layer, and the p-type cladding layer being provided over a semi-polar semiconductor surface of a hexagonal nitride semiconductor,
the n-type cladding layer, the active layer, and the p-type cladding layer being arranged along a normal axis of the semi-polar semiconductor surface,
the semi-polar semiconductor surface tilting toward an m-axis of the hexagonal nitride semiconductor away from a plane orthogonal to a reference axis by an angle of not less than 63 degrees and smaller than 80 degrees, the reference axis extending along a c-axis of the hexagonal nitride semiconductor,
the active layer being provided between the n-type cladding layer and the p-type cladding layer,
the active layer generates light having a peak wavelength within a range of 480 to 600 nm,
a refractive index of the n-type cladding layer and a refractive index of the p-type cladding layer being smaller than a refractive index of GaN, and
a thickness of the n-type cladding layer being not less than 2 μm and a thickness of the p-type cladding layer being not less than 500 nm.

2. The nitride semiconductor laser device according to claim 1, wherein the epitaxial layer comprises ternary InGaN and has an indium content of not less than 0.2.

3. The nitride semiconductor laser device according to claim 1, wherein a total thickness of the n-type cladding layer and the p-type cladding layer is not less than 3 μm.

4. The nitride semiconductor laser device according to claim 1, wherein a core semiconductor region is provided between the n-type cladding layer and the p-type cladding layer and includes the active layer, and a maximum refractive index of the core semiconductor region is not less than a refractive index of GaN.

5. The nitride semiconductor laser device according to claim 1, further comprising:
a support base comprising a hexagonal group-III nitride semiconductor,
the support base comprising the semi-polar semiconductor surface, and
the n-type cladding layer, the active layer, and the p-type cladding layer being sequentially provided over the semi-polar semiconductor surface.

6. The nitride semiconductor laser device according to claim 1, wherein the n-type cladding layer has an indium content of not less than 0.01 and the n-type cladding layer has an aluminum content of not less than 0.03.

7. The nitride semiconductor laser device according to claim 1, wherein the p-type cladding layer has an indium content of not less than 0.01 and the p-type cladding layer has an aluminum content of not less than 0.03.

8. The nitride semiconductor laser device according to claim 1, wherein
the first nitride semiconductor of the n-type cladding layer comprises gallium as a group-III constituent, and
the second nitride semiconductor of the p-type cladding layer comprises gallium as a group-III constituent.

9. The nitride semiconductor laser device according to claim 1, further comprising:
a first GaN optical guiding layer provided between the n-type cladding layer and the active layer;
a first InGaN optical guiding layer provided between the first GaN optical guiding layer and the active layer;
a second GaN optical guiding layer provided between the p-type cladding layer and the active layer; and
a second InGaN optical guiding layer provided between the second GaN optical guiding layer and the active layer.

10. The nitride semiconductor laser device according to claim 1, further comprising: an electron blocking layer provided between the p-type cladding layer and the active layer, the semi-polar semiconductor surface comprising GaN, the electron blocking layer comprising GaN, and the electron blocking layer being provided between two InGaN layers with junctions.

11. The nitride semiconductor laser device according to claim 1, wherein the semi-polar semiconductor surface tilts by an angle of not less than 70 degrees and smaller than 80 degrees.

12. The nitride semiconductor laser device according to claim 1, wherein the first nitride semiconductor of the n-type cladding layer has an indium content and an aluminum content such that a lattice constant of an a-axis thereof matches a lattice constant of an a-axis of the hexagonal nitride semiconductor.

13. The nitride semiconductor laser device according to claim 1, wherein the second nitride semiconductor of the p-type cladding layer has an indium content and an aluminum content such that a lattice constant of an a-axis thereof matches a lattice constant of an a-axis of the hexagonal nitride semiconductor.

14. The nitride semiconductor laser device according to claim 1, wherein the first nitride semiconductor of the n-type cladding layer has an indium content and an aluminum content such that a lattice constant of a c-axis thereof matches a lattice constant of a c-axis of the hexagonal nitride semiconductor.

15. The nitride semiconductor laser device according to claim 1, wherein the second nitride semiconductor of the p-type cladding layer has an indium content and an aluminum content such that a lattice constant of a c-axis thereof matches a lattice constant of a c-axis of the hexagonal nitride semiconductor.

16. The nitride semiconductor laser device according to claim 1, wherein
the second nitride semiconductor of the p-type cladding layer has an indium content and an aluminum content such that lattice constants of a c-axis thereof and an a-axis thereof do not match lattice constants of a c-axis and an a-axis of the hexagonal nitride semiconductor, respectively, and
the first nitride semiconductor of the n-type cladding layer has an indium content and an aluminum content such that lattice constants of a c-axis and an a-axis do not match lattice constants of a c-axis and an a-axis of the hexagonal nitride semiconductor.

17. The nitride semiconductor laser device according to claim 1, wherein
the second nitride semiconductor of the p-type cladding layer has an indium content and an aluminum content such that one of a lattice constant of a c-axis thereof and a lattice constant of an a-axis thereof matches a lattice constant of a corresponding one of the c-axis and the a-axis of the hexagonal nitride semiconductor, and
the first nitride semiconductor of the n-type cladding layer has an indium content and an aluminum content such that a lattice constant of the other of the c-axis and the a-axis thereof matches a lattice constant of a corresponding one of the c-axis and the a-axis of the hexagonal nitride semiconductor.

18. An epitaxial substrate of a nitride semiconductor laser device, comprising:
an n-type cladding layer comprising a first nitride semiconductor, the first nitride semiconductor comprising indium and aluminum as group-III constituents;
an active layer having an epitaxial layer, the epitaxial layer comprising a nitride semiconductor, and the nitride semiconductor comprising indium as a group-III constituent;
a p-type cladding layer comprising a second nitride semiconductor, the second nitride semiconductor comprising indium and aluminum as group-III constituents; and
a substrate comprising a hexagonal nitride semiconductor and having a semi-polar semiconductor surface,
the n-type cladding layer, the active layer, and the p-type cladding layer being provided over the semi-polar semiconductor surface comprising the hexagonal nitride semiconductor,
the n-type cladding layer, the active layer, and the p-type cladding layer being arranged along a normal axis of the semi-polar semiconductor surface,
the semi-polar semiconductor surface tilts by an angle of not less than 63 degrees and smaller than 80 degrees toward an m-axis of the hexagonal nitride semiconductor away from a plane orthogonal to a reference axis, the reference axis extending along a c-axis of the hexagonal nitride semiconductor,
the active layer being provided between the n-type cladding layer and the p-type cladding layer,
the active layer generating light having a peak wavelength in a range of 480 to 600 nm,
a refractive index of the n-type cladding layer and a refractive index of the p-type cladding layer being smaller than a refractive index of GaN,
the n-type cladding layer has a thickness of not less than 2 μm, and
the p-type cladding layer has thickness of not less than 500 nm.

19. The epitaxial substrate according to claim 18, wherein the epitaxial layer comprises ternary InGaN having an indium content of not less than 0.2.

20. The epitaxial substrate according to claim 18, wherein a total thickness of the n-type cladding layer and the p-type cladding layer is not less than 3 μm.

21. The epitaxial substrate according to claim 18, wherein the semi-polar semiconductor surface tilts by an angle of not less than 70 degrees and smaller than 80 degrees.

22. The epitaxial substrate according to claim 18, wherein
an indium content of the n-type cladding layer is not less than 0.01 and an aluminum content of the n-type cladding layer is not less than 0.03, and
an indium content of the p-type cladding layer is not less than 0.01 and an aluminum content of the p-type cladding layer is not less than 0.03.

23. The epitaxial substrate according to claim 18, wherein
the first nitride semiconductor of the n-type cladding layer has an indium content and an aluminum content such that a lattice constant of an a-axis thereof matches a lattice constant of an a-axis of the hexagonal nitride semiconductor.
the second nitride semiconductor of the p-type cladding layer has an indium content and an aluminum content such that a lattice constant of an a-axis thereof matches a lattice constant of an a-axis of the hexagonal nitride semiconductor.

24. The epitaxial substrate according to claim 18, wherein
the first nitride semiconductor of the n-type cladding layer has an indium content and an aluminum content such that a lattice constant of a c-axis thereof matches a lattice constant of a c-axis of the hexagonal nitride semiconductor, and
the second nitride semiconductor of the p-type cladding layer has an indium content and an aluminum content such that a lattice constant of a c-axis thereof matches a lattice constant of a c-axis of the hexagonal nitride semiconductor.

25. The epitaxial substrate according to claim 18, wherein
the second nitride semiconductor of the p-type cladding layer has an indium content and an aluminum content such that lattice constants of a c-axis thereof and an a-axis thereof do not match lattice constants of a c-axis and an a-axis of the hexagonal nitride semiconductor, respectively, and
the first nitride semiconductor of the n-type cladding layer has an indium content and an aluminum content such that lattice constants of a c-axis thereof and an a-axis thereof do not match lattice constants of a c-axis and an a-axis of the hexagonal nitride semiconductor, respectively.

26. A method of fabricating a nitride semiconductor laser device, comprising the steps of:
preparing a substrate, the substrate having a semi-polar semiconductor surface comprising a nitride semiconductor;
growing an n-type cladding layer over the semi-polar semiconductor surface, the n-type cladding layer having a thickness of not less than 2 μm;
growing an active layer over the semi-polar semiconductor surface after growing the n-type cladding layer, the active layer generating light of a peak wavelength in a range of 480 to 600 nm; and
growing a p-type cladding layer over the semi-polar semiconductor surface after growing the active layer, the p-type cladding layer having a thickness of not less than 500 nm,
the n-type cladding layer comprising a first nitride semiconductor, the first nitride semiconductor comprising indium and aluminum as group-III constituents,
the p-type cladding layer comprising a second nitride semiconductor, the second nitride semiconductor comprising indium and aluminum as group-III constituents,
the active layer having an epitaxial layer, the epitaxial layer comprising a nitride semiconductor, and the nitride semiconductor comprising indium as a constituent,
the n-type cladding layer, the active layer, and the p-type cladding layer being arranged along a normal axis of the semi-polar semiconductor surface,
the semi-polar semiconductor surface tilting by an angle of not less than 63 degrees and smaller than 80 degrees toward an m-axis of the hexagonal nitride semiconductor from a plane orthogonal to a reference axis, the reference axis extending along a c-axis of the hexagonal nitride semiconductor, and
a refractive index of the n-type cladding layer and a refractive index of the p-type cladding layer being smaller than a refractive index of GaN.

27. The method of producing a nitride semiconductor laser device according to claim 26, further comprising the steps of
growing a p-type contact layer over the semi-polar semiconductor surface after growing the p-type cladding layer; and
growing an electrode in contact with the p-type contact layer,
the epitaxial layer comprising ternary InGaN, and the ternary InGaN having an indium content of not less than 0.2, and
the growth temperature of a growth sequence of the active layer to the p-type contact layer is not less than 950 degrees Celsius.

28. The method of producing a nitride semiconductor laser device according to claim 26, wherein a total thickness of the n-type cladding layer and the p-type cladding layer is not less than 3 μm.

29. The method of producing a nitride semiconductor laser device according to claim 26, wherein the semi-polar semiconductor surface tilts by an angle of not less than 70 degrees and smaller than 80 degrees.

30. The method of producing a nitride semiconductor laser device according to claim 26, further comprising a step of:
growing a gallium nitride layer over the n-type cladding layer at not less than 1000 degrees Celsius, before growing the active layer,
a growth temperature of the n-type cladding layer being not more than 950 degrees Celsius,
a growth temperature of the active layer being not more than 900 degrees Celsius, and
the semi-polar semiconductor surface comprising GaN.

31. The method of producing a nitride semiconductor laser device according to claim 26, wherein
the n-type cladding layer has an indium content of not less than 0.01 and the n-type cladding layer has an aluminum content of not less than 0.03, and
the p-type cladding layer has an indium content of not less than 0.01 and the p-type cladding layer has an aluminum content of not less than 0.03.

32. The method of producing a nitride semiconductor laser device according to claim 26, wherein
the first nitride semiconductor of the n-type cladding layer has an indium content and an aluminum content such that a lattice constant of an a-axis thereof matches a lattice constant of an a-axis of the hexagonal group-III nitride semiconductor, and
the second nitride semiconductor of the p-type cladding layer has an indium content and an aluminum content such that a lattice constant of an a-axis thereof matches a lattice constant of an a-axis of the hexagonal group-III nitride semiconductor.

33. The method of producing a nitride semiconductor laser device according to claim 26, wherein
the first nitride semiconductor of the n-type cladding layer has an indium content and an aluminum content such that a lattice constant of a c-axis thereof matches a lattice constant of a c-axis of the hexagonal nitride semiconductor, and
the second nitride semiconductor of the p-type cladding layer has an indium content and an aluminum content such that a lattice constant of a c-axis thereof matches a lattice constant of a c-axis of the hexagonal nitride semiconductor.

34. The method of producing a nitride semiconductor laser device according to claim 26, wherein
the second nitride semiconductor of the p-type cladding layer has an indium content and an aluminum content such that lattice constants of a c-axis thereof and an a-axis thereof do not match lattice constants of a c-axis and a a-axis of the hexagonal nitride semiconductor, and
the first nitride semiconductor of the n-type cladding layer has an indium content and an aluminum content such that lattice constants of a c-axis thereof and an a-axis thereof do not match lattice constants of a c-axis and a a-axis of the hexagonal nitride semiconductor.

35. The method of producing a nitride semiconductor laser device according to claim 26, wherein
the second nitride semiconductor of the p-type cladding layer has an indium content and an aluminum content such that one of a lattice constant of a c-axis thereof and a lattice constant of an a-axis thereof matches a lattice constant of a corresponding one of a c-axis and an a-axis of the hexagonal nitride semiconductor, and
the first nitride semiconductor of the n-type cladding layer has an indium content and an aluminum content such that a lattice constant of the other of a c-axis thereof and an a-axis thereof matches a lattice constant of a the corresponding one of the c-axis or the a-axis of the hexagonal nitride semiconductor.
